(19) United States
(12) Patent Application Publication
(10) Pub. No.: US 2025/0337522 A1
(43) Pub. Date: Oct. 30, 2025

(54) LOW RATE CODING DESIGN

(71) Applicant: QUALCOMM Incorporated, San Diego, CA (US)

(72) Inventors: Tzu-Hsuan CHOU, San Diego, CA (US); Lin YANG, San Diego, CA (US); Jialing Li CHEN, San Diego, CA (US); Bin TIAN, San Diego, CA (US)

(21) Appl. No.: 18/648,331

(22) Filed: Apr. 26, 2024

(51) Int. Cl. H04L 1/00

(52) U.S. Cl. CPC H04L 1/0042; H04L 1/0057; H04L 1/0059; H04L 1/0067

(57) ABSTRACT

This disclosure provides methods, components, devices and systems for generating and processing codeword transmissions with reduced code rates. According to one aspect, a method for wireless communications at a first wireless node generally includes obtaining a set of data bits; encoding the data bits, based on at least a first nominal code rate, to generate one or more codewords associated with a reduced nominal code rate that is lower than the first nominal code rate; and outputting the one or more codewords.

### TECHNICAL FIELD

This disclosure relates generally to wireless communication, and more specifically, to designs for achieving codewords with low coding rates.

### DESCRIPTION OF THE RELATED TECHNOLOGY

Wireless communication networks may include various types of wireless communication devices including network entities (such as wireless access points (AP) or base stations (BS)), client devices (such as wireless stations (STAs) or user equipment (UEs)), and other wireless nodes. These wireless communication devices may communicate with one another via a variety of technologies and wireless communication protocols, including wireless local area network (WLAN) or Wi-Fi-based protocols or cellular (such as 4G, 5G, or 6G)-based protocols. The wireless communication networks may be capable of supporting communication with multiple users by sharing the available system resources (such as time, frequency, and spatial resources). To enable features or provide improved performance, the wireless communication devices may employ technologies such as orthogonal frequency divisional multiple access (OFDMA), multi-user Multiple-Input Multiple-Output (MU-MIMO), spatial multiplexing, and beamforming. For greater inter-operability, the wireless communication networks may support backwards compatibility (such as supporting legacy wireless communication devices) as well as forward compatibility (such as supporting communication with wireless communication devices compatible with next-generation wireless communication standards).

### SUMMARY

The systems, methods and devices of this disclosure each have several innovative aspects, no single one of which is solely responsible for the desirable attributes disclosed herein.

One innovative aspect of the subject matter described in this disclosure can be implemented in a method for wireless communication by a first wireless node. The method includes obtaining a set of data bits; encoding the set of data bits, based on at least a first nominal code rate, to generate one or more codewords associated with a reduced nominal code rate that is lower than the first nominal code rate; and outputting the one or more codewords.

Another innovative aspect of the subject matter described in this disclosure can be implemented in a method for wireless communication by a first wireless node. The method includes obtaining one or more codewords associated with a reduced nominal code rate; and decoding the one or more codewords, based on at least a first nominal code rate, to recover a set of data bits, wherein the first nominal code rate is higher than the reduced nominal code rate.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows a pictorial diagram of an example wireless communication network.

FIG. 2 shows an example encoding transmit chain.

FIG. 3 shows a table of example encoding parameters.

FIG. 4 shows an example call flow diagram.

FIG. 5 shows an example encoding transmit chain for achieving a reduced code rate.

FIG. 6 shows an example design for achieving a codeword with a reduced code rate.

FIG. 7 shows an example design for decoding a codeword with a reduced code rate.

FIG. 8 shows a table of example encoding parameters.

FIG. 9 shows an example design for achieving a codeword with a reduced code rate.

FIG. 10 shows an example design for achieving a codeword with a reduced code rate.

FIG. 11 shows an example design for decoding a codeword with a reduced code rate.

FIG. 12 shows an example design for achieving a codeword with a reduced code rate.

FIG. 13 shows an example design for decoding a codeword with a reduced code rate.

FIG. 14 shows an example design for decoding a codeword with a reduced code rate.

FIG. 15 shows a flowchart illustrating an example process performable by or at a wireless node.

FIG. 16 shows a flowchart illustrating an example process performable by or at a wireless node.

FIG. 17 shows a block diagram of an example wireless communication device.

Like reference numbers and designations in the various drawings indicate like elements.

### DETAILED DESCRIPTION

The following description is directed to some particular examples for the purposes of describing innovative aspects of this disclosure. However, a person having ordinary skill in the art will readily recognize that the teachings herein can be applied in a multitude of different ways. Some or all of the described examples may be implemented in any device, system or network that is capable of transmitting and receiving radio frequency (RF) signals according to one or more of the Institute of Electrical and Electronics Engineers (IEEE) 802.11 standards, the IEEE 802.15 standards, the Bluetooth® standards as defined by the Bluetooth Special Interest Group (SIG), or the Long Term Evolution (LTE), 3G, 4G, 5G (New Radio (NR)) or 6G standards promulgated by the 3^{rd} Generation Partnership Project (3GPP), among others.

The described examples can be implemented in any suitable device, component, system or network that is capable of transmitting and receiving RF signals according to one or more of the following technologies or techniques: code division multiple access (CDMA), time division multiple access (TDMA), orthogonal frequency division multiplexing (OFDM), frequency division multiple access (FDMA), orthogonal FDMA (OFDMA), single-carrier FDMA (SC-FDMA), spatial division multiple access (SDMA), rate-splitting multiple access (RSMA), multi-user shared access (MUSA), single-user (SU) multiple-input multiple-output (MIMO) and multi-user (MU)-MIMO (MU-MIMO). The described examples also can be implemented using other wireless communication protocols or RF signals suitable for use in one or more of a wireless personal area network (WPAN), a wireless local area network (WLAN), a wireless wide area network (WWAN), a wireless metropolitan area network (WMAN), a non-terrestrial network (NTN), or an internet of things (IOT) network.

Various physical-layer channel coding schemes using binary convolutional code (BCC) and low-density parity-check (LDPC) codes have been introduced for various types of communications, to achieve improved throughput, latency, and reliability. In many systems, LDPC coding is used for user data, while polar coding is used for control information.

LDPC codes generally refer to a class of error-correcting codes widely used in digital communication systems. LDPC codes are characterized by a sparse parity-check matrix, meaning that only a small fraction of its entries are non-zero. This sparsity contributes to efficient encoding and decoding processes. In LDPC encoding, information bits are mapped to codewords through matrix multiplication. The sparse nature of the parity-check matrix allows for a high degree of parallelism in the encoding process, making it computationally efficient.

The LDPC encoding process involves multiplying the information bits by the generator matrix to generate the codeword. Each row of the matrix represents a parity-check equation, and the resulting codeword satisfies all these equations. This process introduces redundancy into the data, enabling the detection and correction of errors during transmission. LDPC codes are known for their excellent error-correction performance.

Certain systems may be designed to achieve high reliability (Ultra high reliability—UHR). Such systems may also be designed to support long transmission ranges, sometimes referred to as an extended long range (ELR) mode, while still achieving relatively robust throughput (e.g., ˜1 Mbps).

Range extension may be achieved by power gain. Some amount of power gain may be achieved via coding gain using lower rate coding, such as lower rate LDPC or lower rate BCC. Aspects of the present disclosure provide various designs for achieving low rate codes.

Particular aspects of the subject matter described in this disclosure can be implemented to realize one or more of the following potential advantages. The low rate codes described herein may help achieve objectives of extended long range transmission while still achieving target throughput. In some examples, low rate codes may be achieved by leveraging existing (higher rate) codes. As a result, certain current encoders and decoders may be reused, which may help avoid the time and expense of extensive development of entirely new encoders and decoders to support the lower rate codes proposed herein.

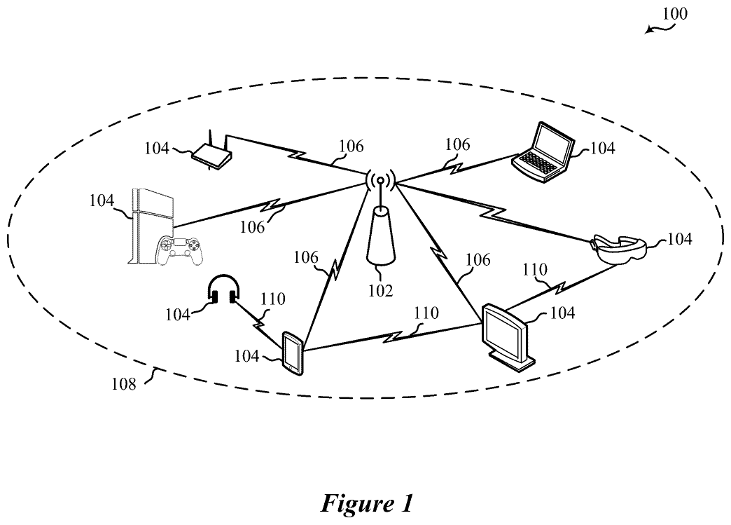

FIG. 1 shows a pictorial diagram of an example wireless communication network 100. According to some aspects, the wireless communication network 100 can be an example of a wireless local area network (WLAN) such as a Wi-Fi network. For example, the wireless communication network 100 can be a network implementing at least one of the IEEE 802.11 family of wireless communication protocol standards, such as defined by the IEEE 802.11-2020 specification or amendments thereof (including, but not limited to, 802.11ay, 802.11ax (also referred to as Wi-Fi 6), 802.11az, 802.11ba, 802.11bc, 802.11bd, 802.11be (also referred to as Wi-Fi 7), 802.11bf, and 802.11bn (also referred to as Wi-Fi 8)) or other WLAN or Wi-Fi standards, such as that associated with the Integrated Millimeter Wave (IMMW) study group. In some other examples, the wireless communication network 100 can be an example of a cellular radio access network (RAN), such as a 5G or 6G RAN that implements one or more cellular protocols such as those specified in one or more 3GPP standards. In some other examples, the wireless communication network 100 can include a WLAN that functions in an interoperable or converged manner with one or more cellular RANs to provide greater or enhanced network coverage to wireless communication devices within the wireless communication network 100 or to enable such devices to connect to a cellular network's core, such as to access the network management capabilities and functionality offered by the cellular network core. In some other examples, the wireless communication network 100 can include a WLAN that functions in an interoperable or converged manner with one or more personal area networks, such as a network implementing Bluetooth or other wireless technologies, to provide greater or enhanced network coverage or to provide or enable other capabilities, functionality, applications or services.

The wireless communication network 100 may include numerous wireless communication devices including a wireless access point (AP) 102 and any number of wireless stations (STAs) 104. While only one AP 102 is shown in FIG. 1, the wireless communication network 100 can include multiple APs 102 (for example, in an extended service set (ESS) deployment, enterprise network or AP mesh network), or may not include any AP at all (for example, in an independent basic service set (IBSS) such as a peer-to-peer (P2P) network or other ad hoc network). The AP 102 can be or represent various different types of network entities including, but not limited to, a home networking AP, an enterprise-level AP, a single-frequency AP, a dual-band simultaneous (DBS) AP, a tri-band simultaneous (TBS) AP, a standalone AP, a non-standalone AP, a software-enabled AP (soft AP), and a multi-link AP (also referred to as an AP multi-link device (MLD)), as well as cellular (such as 3GPP, 4G LTE, 5G or 6G) base stations or other cellular network nodes such as a Node B, an evolved Node B (eNB), a gNB, a transmission reception point (TRP) or another type of device or equipment included in a radio access network (RAN), including Open-RAN (O-RAN) network entities, such as a central unit (CU), a distributed unit (DU) or a radio unit (RU).

Each of the STAs 104 also may be referred to as a mobile station (MS), a mobile device, a mobile handset, a wireless handset, an access terminal (AT), a user equipment (UE), a subscriber station (SS), or a subscriber unit, among other examples. The STAs 104 may represent various devices such as mobile phones, other handheld or wearable communication devices, netbooks, notebook computers, tablet computers, laptops, Chromebooks, augmented reality (AR), virtual reality (VR), mixed reality (MR) or extended reality (XR) wireless headsets or other peripheral devices, wireless earbuds, other wearable devices, display devices (for example, TVs, computer monitors or video gaming consoles), video game controllers, navigation systems, music or other audio or stereo devices, remote control devices, printers, kitchen appliances (including smart refrigerators) or other household appliances, key fobs (for example, for passive keyless entry and start (PKES) systems), Internet of Things (IoT) devices, and vehicles, among other examples.

A single AP 102 and an associated set of STAs 104 may be referred to as an infrastructure basic service set (BSS), which is managed by the respective AP 102. FIG. 1 additionally shows an example coverage area 108 of the AP 102, which may represent a basic service area (BSA) of the wireless communication network 100. The BSS may be identified by STAs 104 and other devices by a service set identifier (SSID), as well as a basic service set identifier (BSSID), which may be a medium access control (MAC) address of the AP 102. The AP 102 may periodically broadcast beacon frames (“beacons”) including the BSSID to enable any STAs 104 within wireless range of the AP 102 to “associate” or re-associate with the AP 102 to establish a respective communication link 106 (hereinafter also referred to as a “Wi-Fi link”), or to maintain a communication link 106, with the AP 102. For example, the beacons can include an identification or indication of a primary channel used by the respective AP 102 as well as a timing synchronization function (TSF) for establishing or maintaining timing synchronization with the AP 102. The AP 102 may provide access to external networks to various STAs 104 in the wireless communication network 100 via respective communication links 106.

To establish a communication link 106 with an AP 102, each of the STAs 104 is configured to perform passive or active scanning operations (“scans”) on frequency channels in one or more frequency bands (for example, the 2.4 GHz, 5 GHZ, 6 GHz, 45 GHz, or 60 GHz bands). To perform passive scanning, a STA 104 listens for beacons, which are transmitted by respective APs 102 at periodic time intervals referred to as target beacon transmission times (TBTTs). To perform active scanning, a STA 104 generates and sequentially transmits probe requests on each channel to be scanned and listens for probe responses from APs 102. Each STA 104 may identify, determine, ascertain, or select an AP 102 with which to associate in accordance with the scanning information obtained through the passive or active scans, and to perform authentication and association operations to establish a communication link 106 with the selected AP 102. The selected AP 102 assigns an association identifier (AID) to the STA 104 at the culmination of the association operations, which the AP 102 uses to track the STA 104.

As a result of the increasing ubiquity of wireless networks, a STA 104 may have the opportunity to select one of many BSSs within range of the STA 104 or to select among multiple APs 102 that together form an extended service set (ESS) including multiple connected BSSs. For example, the wireless communication network 100 may be connected to a wired or wireless distribution system that may enable multiple APs 102 to be connected in such an ESS. As such, a STA 104 can be covered by more than one AP 102 and can associate with different APs 102 at different times for different transmissions. Additionally, after association with an AP 102, a STA 104 also may periodically scan its surroundings to find a more suitable AP 102 with which to associate. For example, a STA 104 that is moving relative to its associated AP 102 may perform a “roaming” scan to find another AP 102 having more desirable network characteristics such as a greater received signal strength indicator (RSSI) or a reduced traffic load.

In some examples, STAs 104 may form networks without APs 102 or other equipment other than the STAs 104 themselves. One example of such a network is an ad hoc network (or wireless ad hoc network). Ad hoc networks may alternatively be referred to as mesh networks or peer-to-peer (P2P) networks. In some examples, ad hoc networks may be implemented within a larger network such as the wireless communication network 100. In such examples, while the STAs 104 may be capable of communicating with each other through the AP 102 using communication links 106, STAs 104 also can communicate directly with each other via direct wireless communication links 110. Additionally, two STAs 104 may communicate via a direct wireless communication link 110 regardless of whether both STAs 104 are associated with and served by the same AP 102. In such an ad hoc system, one or more of the STAs 104 may assume the role filled by the AP 102 in a BSS. Such a STA 104 may be referred to as a group owner (GO) and may coordinate transmissions within the ad hoc network. Examples of direct wireless communication links 110 include Wi-Fi Direct connections, connections established by using a Wi-Fi Tunneled Direct Link Setup (TDLS) link, and other P2P group connections.

In some networks, the AP 102 or the STAs 104, or both, may support applications associated with high throughput or low-latency requirements, or may provide lossless audio to one or more other devices. For example, the AP 102 or the STAs 104 may support applications and use cases associated with ultra-low-latency (ULL), such as ULL gaming, or streaming lossless audio and video to one or more personal audio devices (such as peripheral devices) or AR/VR/MR/XR headset devices. In scenarios in which a user uses two or more peripheral devices, the AP 102 or the STAs 104 may support an extended personal audio network enabling communication with the two or more peripheral devices. Additionally, the AP 102 and STAs 104 may support additional ULL applications such as cloud-based applications (such as VR cloud gaming) that have ULL and high throughput requirements.

As indicated above, in some implementations, the AP 102 and the STAs 104 may function and communicate (via the respective communication links 106) according to one or more of the IEEE 802.11 family of wireless communication protocol standards. These standards define the WLAN radio and baseband protocols for the physical (PHY) and MAC layers. The AP 102 and STAs 104 transmit and receive wireless communications (hereinafter also referred to as “Wi-Fi communications” or “wireless packets”) to and from one another in the form of PHY protocol data units (PPDUs).

Each PPDU is a composite structure that includes a PHY preamble and a payload that is in the form of a PHY service data unit (PSDU). The information provided in the preamble may be used by a receiving device to decode the subsequent data in the PSDU. In instances in which a PPDU is transmitted over a bonded or wideband channel, the preamble fields may be duplicated and transmitted in each of multiple component channels. The PHY preamble may include both a legacy portion (or “legacy preamble”) and a non-legacy portion (or “non-legacy preamble”). The legacy preamble may be used for packet detection, automatic gain control and channel estimation, among other uses. The legacy preamble also may generally be used to maintain compatibility with legacy devices. The format of, coding of, and information provided in the non-legacy portion of the preamble is associated with the particular IEEE 802.11 wireless communication protocol to be used to transmit the payload.

The APs 102 and STAs 104 in the wireless communication network 100 may transmit PPDUs over an unlicensed spectrum, which may be a portion of spectrum that includes frequency bands traditionally used by Wi-Fi technology, such as the 2.4 GHZ, 5 GHz, 6 GHZ, 45 GHz, and 60 GHz bands. Some examples of the APs 102 and STAs 104 described herein also may communicate in other frequency bands that may support licensed or unlicensed communications. For example, the APs 102 or STAs 104, or both, also may be capable of communicating over licensed operating bands, where multiple operators may have respective licenses to operate in the same or overlapping frequency ranges. Such licensed operating bands may map to or be associated with frequency range designations of FR1 (410 MHz-7.125 GHZ), FR2 (24.25 GHz-52.6 GHz), FR3 (7.125 GHz-24.25 GHZ), FR4a or FR4-1 (52.6 GHz-71 GHZ), FR4 (52.6 GHz-114.25 GHz), and FR5 (114.25 GHZ-300 GHz).

Each of the frequency bands may include multiple sub-bands and frequency channels (also referred to as subchannels). The terms “channel” and “subchannel” may be used interchangeably herein, as each may refer to a portion of frequency spectrum within a frequency band (for example, a 20 MHz, 40 MHz, 80 MHz, or 160 MHz portion of frequency spectrum) via which communication between two or more wireless communication devices can occur. For example, PPDUs conforming to the IEEE 802.11n, 802.11ac, 802.11ax, 802.11be and 802.11bn standard amendments may be transmitted over one or more of the 2.4 GHz, 5 GHZ, or 6 GHz bands, each of which is divided into multiple 20 MHz channels. As such, these PPDUs are transmitted over a physical channel having a minimum bandwidth of 20 MHz, but larger channels can be formed through channel bonding. For example, PPDUs may be transmitted over physical channels having bandwidths of 40 MHz, 80 MHz, 160 MHZ, 240 MHz, 320 MHz, 480 MHz, or 640 MHz by bonding together multiple 20 MHz channels.

An AP 102 may determine or select an operating or operational bandwidth for the STAs 104 in its BSS and select a range of channels within a band to provide that operating bandwidth. For example, the AP 102 may select sixteen 20 MHz channels that collectively span an operating bandwidth of 320 MHz. Within the operating bandwidth, the AP 102 may typically select a single primary 20 MHz channel on which the AP 102 and the STAs 104 in its BSS monitor for contention-based access schemes. In some examples, the AP 102 or the STAs 104 may be capable of monitoring only a single primary 20 MHz channel for packet detection (for example, for detecting preambles of PPDUs). Conventionally, any transmission by an AP 102 or a STA 104 within a BSS must involve transmission on the primary 20 MHz channel. As such, in conventional systems, the transmitting device must contend on and win a TXOP on the primary channel to transmit anything at all. However, some APs 102 and STAs 104 supporting ultra-high reliability (UHR) communications or communication according to the IEEE 802.11bn standard amendment can be configured to operate, monitor, contend and communicate using multiple primary 20 MHz channels. Such monitoring of multiple primary 20 MHz channels may be sequential such that responsive to determining, ascertaining or detecting that a first primary 20 MHz channel is not available, a wireless communication device may switch to monitoring and contending using a second primary 20 MHz channel. Additionally, or alternatively, a wireless communication device may be configured to monitor multiple primary 20 MHz channels in parallel. In some examples, a first primary 20 MHz channel may be referred to as a main primary (M-Primary) channel and one or more additional, second primary channels may each be referred to as an opportunistic primary (O-Primary) channel. For example, if a wireless communication device measures, identifies, ascertains, detects, or otherwise determines that the M-Primary channel is busy or occupied (such as due to an overlapping BSS (OBSS) transmission), the wireless communication device may switch to monitoring and contending on an O-Primary channel. In some examples, the M-Primary channel may be used for beaconing and serving legacy client devices and an O-Primary channel may be specifically used by non-legacy (for example, UHR- or IEEE 802.11bn-compatible) devices for opportunistic access to spectrum that may be otherwise under-utilized.

### Overview of Low Density Parity Codes

In order for transmissions over the air interface to obtain a low block error rate (BLER) while still achieving very high data rates, channel coding may be used. That is, wireless communication may generally utilize a suitable error correcting block code. In a typical block code, an information message or sequence is split up into code blocks (CBs), and an encoder (e.g., a CODEC) at the transmitting device then mathematically adds redundancy to the information message. Exploitation of this redundancy in the encoded information message can improve the reliability of the message, enabling correction for any bit errors that may occur due to the noise.

Data coding may be implemented in multiple manners. In early 5G NR specifications, user data is coded using quasi-cyclic low-density parity check (LDPC) with two different base graphs: one base graph is used for large code blocks and/or high code rates, while the other base graph is used otherwise. Control information and the physical broadcast channel (PBCH) are coded using Polar coding, based on nested sequences. For these channels, puncturing, shortening, and repetition are used for rate matching.

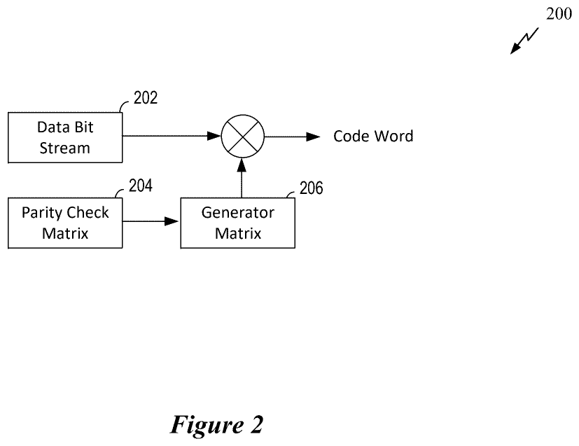

FIG. 2 depicts an example LDPC encoding transmit chain 200. As illustrated, the LDPC encoding transmit chain 200 includes a parity check matrix 204 and generator matrix 206 to encode a data stream 202 to generate an LDPC code word.

Rate matching may be performed to adapt the code block size to the modulation and coding scheme (MCS) chosen for transmission. This step may involve puncturing or repeating bits to match the desired code rate. Pilot symbols, which are known reference symbols, may be inserted into the OFDM symbol to aid in channel estimation and equalization. QAM data symbols may be interleaved to improve performance in the presence of frequency-selective fading. Finally, a mapping block 208 maps the encoded bits to a constellation, generating modulation symbols.

LDPC codes can be represented by bipartite graphs (often referred to as “Tanner graphs”). In a bipartite graph, a set of variable nodes corresponds to bits of a code word (e.g., information bits or systematic bits), and a set of check nodes correspond to a set of parity-check constraints that define the code. Edges in the graph connect variable nodes to check nodes. Thus, the nodes of the graph are separated into two distinctive sets and with edges connecting nodes of two different types, variable and check.

Graphs as used in LDPC coding may be characterized in a variety of manners. A lifted code is created by copying a bipartite base graph (G) (or a protograph), a number of times, Z. The number of times is referred to herein as the lifting, lifting size, or lifting size value. A variable node and a check node are considered “neighbors” if they are connected by an “edge” (i.e., the line connecting the variable node and the check node) in the graph. In addition, for each edge (e) of the bipartite base graph (G), a permutation (generally an integer value associated with the edge permutation that is represented by k and referred to as the lifting value) is applied to the Z copies of edge (e) to interconnect the Z copies of G. A bit sequence having a one-to-one association with the variable node sequence is a valid code word if and only if, for each check node, the bits associated with all neighboring variable nodes sum to 0 modulo 2 (i.e., they include an even number of 1's). The resulting LDPC code may be quasi-cyclic (QC) if the permutations (liftings values) used are cyclic.

A received LDPC code word can be decoded to produce a reconstructed version of the original code word. In the absence of errors, or in the case of correctable errors, decoding can be used to recover the original data unit that was encoded. Redundant bits may be used by decoders to detect and correct bit errors. LDPC decoder(s) generally operate by iteratively performing local calculations and passing those results by exchanging messages within the bipartite graph along the edges, and updating these messages by performing computations at the nodes based on the incoming messages. These steps may be repeated several times. For example, each variable node in the graph may initially be provided with a “soft bit” (e.g., representing the received bit of the code word) that indicates an estimate of the associated bit's value as determined by observations from the communications channel. Using these soft bits the LDPC decoders may update messages by iteratively reading them, or some portion thereof, from memory and writing an updated message, or some portion thereof, back to, memory. The update operations are typically based on the parity check constraints of the corresponding LDPC code. In implementations for lifted LDPC codes, messages on like edges are often processed in parallel.

LDPC codes designed for high speed applications often use quasi-cyclic constructions with large lifting factors and relatively small base graphs to support high parallelism in encoding and decoding operations. LDPC codes with higher code rates (e.g., the ratio of the message length to the codeword length) tend to have relatively fewer parity checks. If the number of base parity checks is smaller than the degree of a variable node (e.g., the number of edges connected to a variable node), then, in the base graph, that variable node is connected to at least one of the base parity checks by two or more edges (e.g., the variable node may have a “double edge”). If the number of base parity checks is smaller than the degree of a variable node (e.g., the number of edges connected to a variable node), then, in the base graph, that variable node is connected to at least one of the base parity checks by two or more edges. Having a base variable node and a base check node connected by two or more edges is generally undesirable for parallel hardware implementation purposes. For example, such double edges may result in multiple concurrent read and write operations to the same memory locations, which in turn may create data coherency problems. A double edge in a base LDPC code may trigger parallel reading of the same soft bit value memory location twice during a single parallel parity check update. Thus, additional circuitry is typically needed to combine the soft bit values that are written back to memory, so as to properly incorporate both updates. Eliminating double edges in the LDPC code helps to avoid this extra complexity.

Puncturing is the act of removing bits from a codeword to yield a shorter codeword. Thus, punctured variable nodes correspond to codeword bits that are not actually transmitted. Puncturing a variable node in an LDPC code creates a shortened code (e.g. due to the removal of a bit), while also effectively removing a check node. Specifically, for a matrix representation of an LDPC code, including bits to be punctured, where the variable node to be punctured has a degree of one (such a representation may be possible through row combining provided the code is proper), puncturing the variable node removes the associated bit from the code and effectively removes its single neighboring check node from the graph. As a result, the number of check nodes in the graph is reduced by one.

### Overview of Coding and Rate Matching

Certain systems (e.g., 802.11be, referred to as extremely high throughput or EHT), may apply a two-step padding process to a PPDU. In such cases, a pre-FEC (forward error correction) padding process including both pre-FEC MAC and pre-FEC PHY padding may be applied before conducting FEC coding. A post-FEC PHY padding process may also applied on the FEC encoded bits.

Four pre-FEC padding boundaries may partition the last OFDM symbol of an EHT PPDU into four symbol segments. The pre-FEC padding may pad toward one of the four possible boundaries. The four pre-FEC padding boundaries are represented by a pre-FEC padding factor parameter a.

The encoding process for single user (SU) and multi-user (MU) transmissions in systems, for PPDUs (e.g., EHT) may involve various steps. For example, these steps may include a first step of determining an LDPC pre-FEC padding boundary, a second step of determine LDPC codeword size and number of codewords, a third step of shortening, a fourth step of puncturing and/or repetition, and a fifth step of finalizing the LDPC/BCC pre-FEC padding and post-FEC padding.

For the first step, in an EHT MU PPDU transmission, the transmitter may first compute the number of data bits left in the last OFDM symbol for user u as in the following equation:

$${N}_{Excess , u} = ( 8 \cdot {APEP}_{L E N G T {H}_{u}} + {N}_{t a i l , u} + {N}_{s e r v i c e} ) mod {N}_{D B P S , u} ;$$

where APEP_LENGTHu is the TXVECTOR parameter APEP_LENGTH for the u-th user; N_{tail,u} is the number of tails bits per encoder for user u, and N_{tail,u}=6 for BCC and N_{tail,u}=0 for LDPC; N_{service}=16 is the number of bits in the SERVICE field; N_{DBPS,u}=floor(N_{CBPS,u}·Rᵤ) is the number of data bits per OFDM symbol for the u-th user, where Ry is the nominal coding rate for the u-th user; N_{CBPS,u}=N_{SD,u}·N_{ss,u}·N_{BPSCS,u} is the number of coded bits per OFDM symbol for user u, in which N_{SD,u} is the N_{SD} (effective number of data tones carrying unique data in one OFDM symbol) value corresponding to the occupied RU or MRU size of the u-th user, N_{ss,u} is the number of spatial streams for the u-th user, N_{BPSCS,u} is the number of coded bits per OFDM symbol per spatial stream for user u.

Based on N_{Excess,u} the transmitter then computes the initial number of symbol segments in the initial last OFDM symbol (an initial pre-FEC padding factor value a_{init,u}) and the initial number of OFDM symbols, N_{SYM,init,u}, for user u using the following equations:

$${a}_{init , u} = \{ \begin{matrix}4 , & if {N}_{Excess , u} = 0 \\ min ( ⌈ \frac{{N}_{Excess , u}}{{N}_{DBPS , short , u}} ⌉ , 4 ) , & otherwise\end{matrix} ; and$$

$${N}_{SYM , init , u} = ⌈ \frac{8 \cdot {APEP}_{{LENGTH}_{u}} + {N}_{tail , u} + {N}_{service}}{{N}_{DBPS , u}} ⌉ ,$$

where im lookk_{DBPS,short,u}=N_{CBPS,short,u}·Rᵤ, in which N_{CBPS,short,u}=N_{SD,short,u}·N_{ss,u}·N_{BPSCS,u}, in which N_{SD,short,u} is the N_{SD,short} (effective number of data tones carrying unique data in each symbol segment of the first three symbol segments) value corresponding to the occupied RU or MRU size of the u-th user.

Among all the users, the transmitter may derive the set of the user indices S, with the longest encoded packet duration as in the following equation, and select one value from the set as uₘₐₓ:

$$S = arg {max}_{0 \leq u \leq {N}_{user , total} - 1} ( {N}_{SYM , init , u} - 1 + \frac{{a}_{init , u}}{4} ) ,$$

where arg max ƒ(x):={x∈[0, N_{user,total}−1]: ƒ(y)≤ƒ(x) for all y∈[0, N_{user,total}−1]}. Then the common aᵢₙᵢₜ and N_{SYM,init} values among all the users may be derived using the following equations:

$${N}_{SYM , init} = {N}_{SYM , init , {u}_{max}} ; and$$

$${a}_{init} = {a}_{init , {u}_{max}} .$$

Next, each user's initial number of data bits N_{DBPS,last,init}, and initial number of coded bits N_{CBPS,last,init,u} in its last OFDM symbol may be calculated as shown in the following equations, respectively:

$${N}_{DBPS , last , init , u} = \{ \begin{matrix}{a}_{init} \cdot {N}_{DBPS , short , u} & if {a}_{init} < 4 \\ {N}_{DBPS , u} & if {a}_{init} = 4\end{matrix}$$

$${N}_{CBPS , last , init , u} = \{ \begin{matrix}{a}_{init} \cdot {N}_{CBPS , short , u} & if {a}_{init} < 4 \\ {N}_{CBPS , u} & if {a}_{init} = 4\end{matrix} .$$

For each user with LDPC encoding, the parameters N_{pld,u} and N_{avbits,u} may be computed using the following equations, respectively:

$${N}_{pld , u} = ( {N}_{SYM , init} - 1 ) {N}_{DBPS , u} + {N}_{DBPS , last , init , u}$$

$${N}_{avbits , u} = ( {N}_{SYM , init} - 1 ) {N}_{CBPS , u} + {N}_{CBPS , last , init , u}$$

where N_{pld,u} is the PHY payload size, the number of data bits including pre-FEC padding bits, that fits in the PHY payload boundary (or called pre-FEC padding boundary) which is the end of the symbol segment aᵢₙᵢₜ in the OFDM symbol N_{SYM,init} and N_{avbits,u} is the number of PHY coded bits that fits in the current PHY coded bits boundary which is the end of the symbol segment aᵢₙᵢₜ in the OFDM symbol N_{SYM,init}.

The effective code rate of u, based on these two values is, thus:

$${eCR}_{u} = \frac{{N}_{pld , u}}{{N}_{avbits , u}} = \frac{( {N}_{SYM , init} - 1 ) {N}_{DBPS , u} + {N}_{DBPS , last , init , u}}{( {N}_{SYM , init} - 1 ) {N}_{CBPS , u} + {N}_{CBPS , last , init , u}} = {R}_{u} .$$

In some cases, the PHY coded bits boundary may be adjusted by adding one or more OFDM symbols and/or fraction of symbol (e.g., one or more symbol segments) to accommodate more PHY coded bits, which could lower the effective code rate and reduce puncturing ratio.

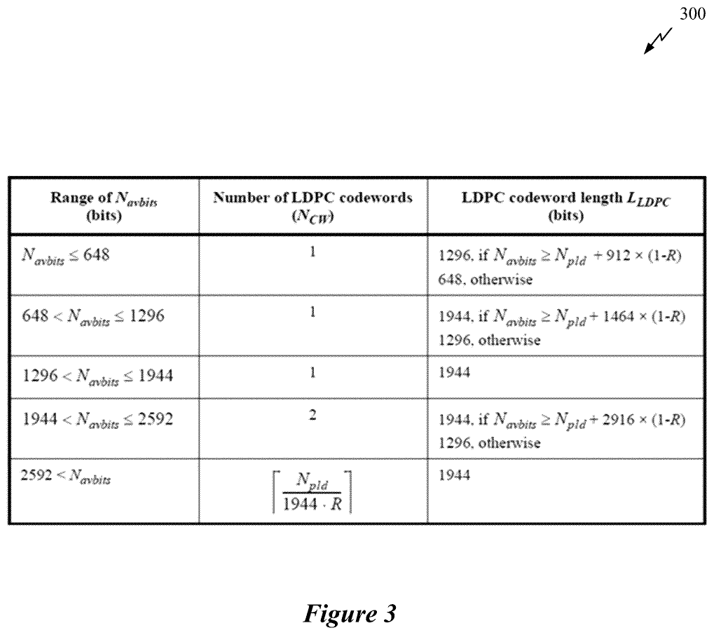

For the second step, the transmitter may compute the integer number of LDPC codewords to be transmitted for user u, N_{CW,u}, and the length of the codewords to be used for user u, L_{LDPC,u}, in accordance with table 300 shown in FIG. 3.

For the third step, the transmitter may compute the number of shortening bits for user u, N_{shrt,u}, to be padded to the N_{pld,u} data bits before encoding, as shown in the following equation:

$${N}_{shrt , u} = max ( 0 , {N}_{CW , u} \cdot {L}_{LDPC , u} \cdot {R}_{u} - {N}_{pld , u} ) .$$

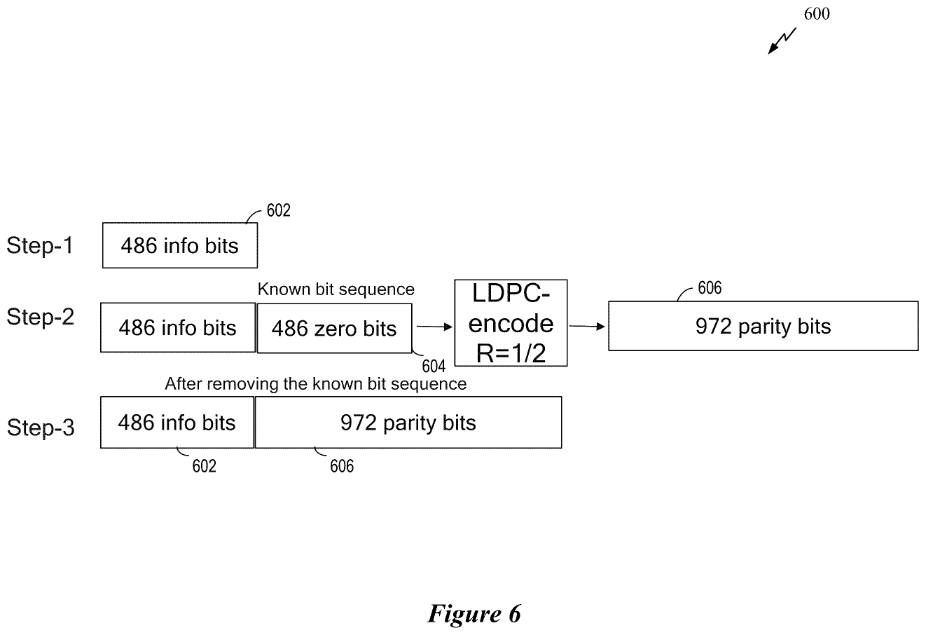

When N_{shrt,u}=0, shortening is not performed. When N_{shrt,u}>0, shortening bits may be equally distributed over all N_{CW,u} codewords with the first rem (N_{shrt,w}, N_{CW,u}) codewords being shortened one bit more than the remaining codewords. As will be described in greater detail below with reference to FIG. 6, shortening bits may be appended after data bits. The shortening bits shall be discarded after encoding.

For the fourth step, the transmitter may compute the number of bits to be punctured for user u, N_{punc,u}, from the codewords after encoding, as follows:

$${N}_{punc , u} = max ( 0 , {N}_{CW , u} \cdot {L}_{LDPC , u} - {N}_{avbits , u} - {N}_{shrt , u} )$$

When N_{punc,u}=0, puncturing is not performed. When N_{punc,u}>0, puncturing bits may be equally distributed over all N_{CW,u} codewords with the first rem (N_{punc,u}, N_{CW,u}) codewords being punctured one bit more than the remaining codewords. Only parity bits may be punctured.

If there is at least one user with LDPC encoding for which the following condition in LDPC encoding process is met:

$$( {N}_{punc , u} > 0.1 \cdot {N}_{CW , u} \cdot {L}_{LDPC , u} \cdot ( 1 - {R}_{u} ) ) AND ( {N}_{shrt} < 1.2 \cdot {N}_{punc , u} \cdot {R}_{u} / ( 1 - {R}_{u} ) )$$

is true OR if:

$${N}_{punc , u} > 0.3 \cdot {N}_{CW , u} \cdot {L}_{LDPC , u} \cdot ( 1 - {R}_{u} )$$

is true, for any user u, all users with LDPC encoding shall increment N_{avbits,u} by an extra symbol segment and recompute N_{punc,u} based on the new N_{avbits,u} value:

$${N}_{avbits , u} = \{ \begin{matrix}{N}_{avbits , u} + {N}_{CBPS , u} - 3 {N}_{CBPS , short , u} , & if {a}_{init} = 3 \\ {N}_{avbits , u} + {N}_{CBPS , short , u} , & otherwise\end{matrix} .$$

The transmitter may then update the common pre-FEC padding factor a and N_{SYM} values for all users as follows:

$$\{ \begin{matrix}{N}_{SYM} = {N}_{SYM , init} + 1 and a = 1 , & if {a}_{init} = 4 \\ {N}_{SYM} = {N}_{SYM , init} and a = {a}_{init} + 1 , & otherwise\end{matrix}$$

It may be noted that the last OFDM symbol is the next OFDM symbol of the initial last OFDM symbol in this case, if aᵢₙᵢₜ=4. Since N_{avbits,u} is updated with a larger value, more PHY coded bits fit in the adjusted PHY coded bits boundary which is the end of the symbol segment a in the OFDM symbol N_{SYM}.

On the other hand, if the above condition in LDPC encoding process is not met by any of the users with LDPC encoding, or if all the users scheduled in the EHT MU PPDU are BCC encoded, no extra symbol segment is added. Then update the common pre-FEC padding factor a and N_{SYM} values for all users as follows:

$${N}_{SYM} = {N}_{SYM , init} and a = {a}_{init} .$$

The transmitter may compute the number of coded bits to be repeated for user u, N_{rep,u}, as follows:

$${N}_{rep , u} = max ( 0 , {N}_{avbits , u} - {N}_{CW , u} \cdot {L}_{LDPC , u} \cdot ( 1 - {R}_{u} ) - {N}_{pld , u} )$$

When N_{rep,u}=0, repetition is not performed. When N_{rep,u}>0, the number of coded bits to be repeated shall be equally distributed over all N_{CW,u} codewords with one more bit repeated for the first rem (N_{rep,u}, N_{CW,u}) codewords than the remaining codewords. The coded bits to be repeated for any codeword shall be copied only from that codeword itself, starting from the beginning of that LDPC codeword (beginning of data bits). It may be noted that, in general, when bits are punctured, coded bits are not repeated and, conversely, when coded bits are repeated, puncturing may not occur.

For the fifth step, for the users with LDPC encoding, the transmitter may update N_{DBPS} of the last OFDM symbol as:

$${N}_{DBPS , last , u} = {N}_{DBPS , last , init , u} .$$

For the users with BCC encoding, update N_{DBPS} of the last OFDM symbol as:

$${N}_{DBPS , last , u} = \{ \begin{matrix}a \cdot {N}_{DBPS , short , u} , & if a < 4 \\ {N}_{DBPS , u} , & if a = 4\end{matrix} .$$

For each user with either LDPC or BCC encoding, update N_{CBPS} of the last OFDM symbol as:

$${N}_{CBPS , last , u} = \{ \begin{matrix}a \cdot {N}_{CBPS , short , u} , & if a < 4 \\ {N}_{CBPS , u} , & if a = 4\end{matrix} .$$

For each user with LDPC encoding, the number of pre-FEC padding bits for the u-th user is computed as:

$${N}_{PAD , Pre - FEC , u} = ( {N}_{SYM , init} - 1 ) {N}_{DBPS , u} + {N}_{DBPS , last , init , u} - 8 \cdot {APEP}_{{LENGTH}_{u}} - {N}_{service}$$

The PHY payload boundary (or called pre-FEC padding boundary) for users using LDPC encoding is still the end of the symbol segment aᵢₙᵢₜ in the OFDM symbol N_{SYM,init}, only determined by N_{SYM,init} and aᵢₙᵢₜ.

For the users with BCC encoding, the number of pre-FEC padding bits for the u-th user is shown in the following equation:

$${N}_{PAD , Pre - FEC , u} = ( {N}_{SYM} - 1 ) {N}_{DBPS , u} + {N}_{DBPS , last , u} - 8 \cdot {APEP}_{{LENGTH}_{u}} - {N}_{tail , u} - {N}_{service} .$$

For users using BCC encoding, both the PHY payload boundary (or called pre-FEC padding boundary) and the PHY coded bits boundary are the same as the end of the symbol segment a in the OFDM symbol N_{SYM}, determined by N_{SYM} and a.

For each user with either LDPC or BCC encoding, the number of post-FEC padding bits in the last symbol is computed as in the following equation:

$${N}_{PAD , Post - FEC , u} = {N}_{CBPS , u} - {N}_{CBPS , last , u} .$$

The post-FEC padding fills the data tones not occupied by PHY coded bits in the last OFDM symbol (e.g., the remaining symbol segments in the last OFDM symbol).

Among the pre-FEC padding bits, the MAC may deliver a PSDU that fills the available octets in the Data field of the EHT PPDU, toward the desired initial pre-FEC padding boundary represented by aᵢₙᵢₜ for users encoded by LDPC, and toward the desired pre-FEC padding boundary represented by a for users encoded by BCC, in the last OFDM symbol. The PHY then determines the number of padding bits to add and appends them to the PSDU. The number of pre-FEC padding bits added by PHY will always be 0 to 7.

### Aspects Related to Low Rate Coding Design

Aspects of the present disclosure may help achieve range extension via coding gain by providing designs for lower rate coding. The designs may be applied to different types of coding, for example, to provide for lower rate LDPC codes and/or binary convolutional codes (BCC). The low code rates proposed herein may help achieve higher power gain that higher rate codes.

In some examples, low rate codes may be achieved by leveraging existing (higher rate) codes. As a result, certain current encoders and decoders may be reused, which may help avoid the time and expense of extensive development of entirely new encoders and decoders to support the lower rate codes proposed herein.

The techniques proposed herein may be used to generate lower rate LDPC codes and to achieve LDPC rate matching for extend extended long range (ELR) modes. The techniques may also be used to generate lower rate BCC codes and BCC rate matching for ELR. As will be described below, existing coding parameters may also be leveraged when determining coding parameters for lower rates proposed herein. For example, nominal codeword sizes of 648, 1296, 1944, and 3888 (=2×1944) may be used.

In this context, code rate generally refers to the ratio of data bits divided by the number of coded bits in a codeword. Nominal code rate generally refers to the code rate defined for encoding (e.g., in 802.11be, nominal code rates include ½, ⅔, ¾, and ⅚). Prior to transmission, various rate matching operations (e.g., shortening, puncturing, and/or repetition) may be performed to ensure a right amount of bits are obtained to match an effective code rate to a desired code rate. Thus, effective code rate in transmission refers to the actual code rate resulted from the rate matching process. Rate matching may be designed to (shorten, puncture, and/or repeat bits to) fit codewords or coded bits into a certain number of OFDM symbols and/or a certain number of symbol segments, that results in an effective code rate in transmission that may be different from the nominal low code rate.

There are various approaches to achieve reduced rate codes. One approach would be to design new generic (e.g., LDPC) coding of a reduced rate R, for example, where R<½. For example, one approach is to design a new parity check matrix of a reduced rate R and each nominal codeword size. With this approach, (existing) nominal codeword sizes may still be used.

As noted above, other approaches may leverage existing nominal code rates (e.g., 11be rate ½, ⅔, ¾, ⅚ LDPC codes) to generate LDPC codes with a reduced target code rate R.

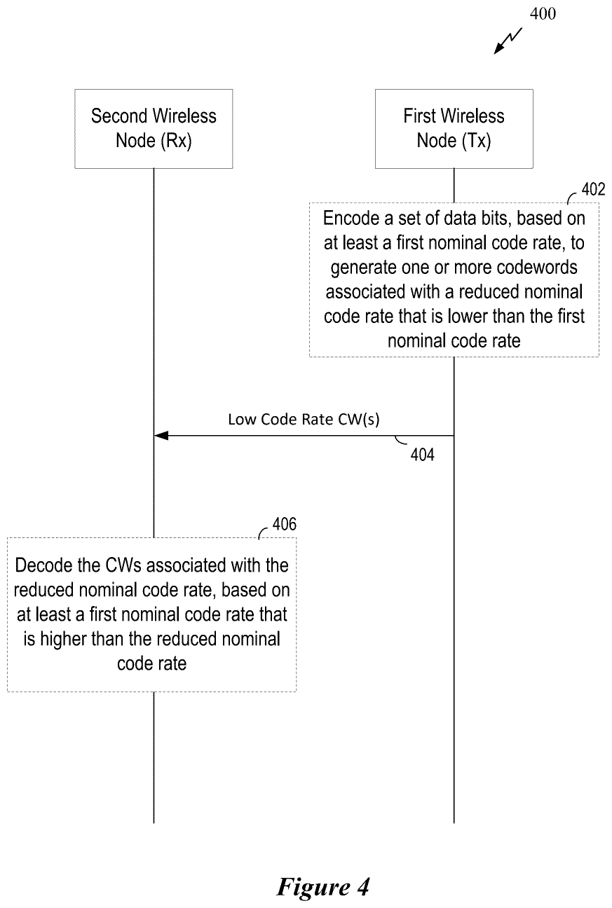

FIG. 4 illustrates an example call flow diagram 400 for low rate code design that may leverage existing nominal code rates, in accordance with aspects of the present disclosure. The example assumes a transmission between a first wireless node (transmitter/Tx) and a second wireless node (receiver/Rx). In some case, the first wireless node and/or the second wireless node may be examples of an AP 102 and/or a STA 104 shown in FIG. 1.

As indicated at 402, the first wireless node encodes a set of data bits, based on at least a first nominal code rate, to generate one or more codewords associated with a reduced nominal code rate that is lower than the first nominal code rate. As indicated at 404, the first wireless node transmits the low code rate codewords (CWs) to the second wireless node.

As indicated at 406, the second wireless node decodes the CWs associated with the reduced nominal code rate, based on at least a first nominal code rate that is higher than the reduced nominal code rate. In other words, as will be described in greater detail below, the second wireless node may utilize decoders based on higher nominal code rates.

There are various methods that may leverage existing nominal code rates (e.g., 11be rate ½, ⅔, ¾, ⅚ LDPC codes) to generate LDPC codes with a reduced target code rate R.

A first method to achieve a reduced nominal code rate may utilize existing nominal codes with repetition to achieve a reduced target code rate R.

According to this method, for example, a transmitter may first generate LDPC codewords based on an existing code rate R0 and a nominal codeword size and then repeat the coded bits N times to obtain an LDPC code of nominal code rate R0/N and the new nominal codeword sizes that of N times the size of the original nominal codeword sizes. As an example, reduced code rates of ¼, ⅙, and ⅛ may be obtained by using a nominal code rate of ½ and 2×, 3×, and 4× repetition (N=2, N=2, and N=2,), respectively. Similarly, a reduced code of ⅓ may be obtained using a nominal code rate of ⅔ and 2× repetition (N=2), a reduced code of ¼ may be obtained using a nominal code rate of ¾ and 3× repetition (N=3), and a reduced code of ⅙ may be obtained using a nominal code rate of ⅚ and 5× repetition (N=5).

A second method to achieve a reduced nominal code rate may utilize a concatenation of existing nominal codes to achieve a reduced target code rate R.

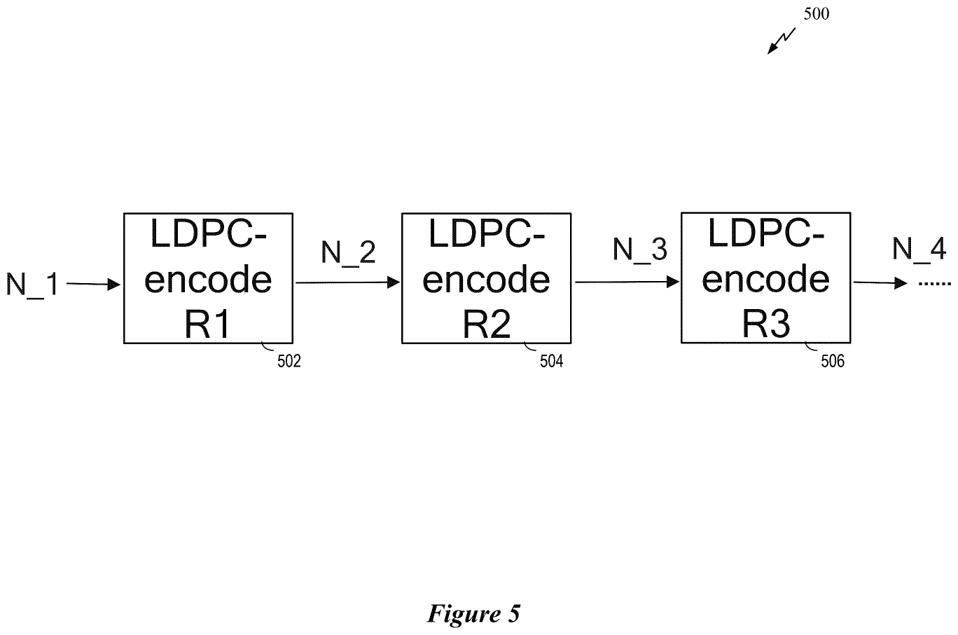

According to this approach, for example, a transmitter may first generate LDPC codewords through a first encoder of rate R1, and then use the LDPC codewords as input to a second encoder of rate R2 to generate new LDPC codewords to get an LDPC code of nominal code rate R1*R2. As illustrated in example 500 of FIG. 5, more than 2 encoders (e.g., 502, 504, and 506) may be concatenated in this way, with a final nominal code rate being a product of the code rates of the individual encoders (e.g., R1*R2*R3).

FIG. 5 illustrates an example diagram 500 of concatenated codes. In the illustrated example, a first LDPC encoder 502 has a first nominal code rate R1, a second LDPC encoder 504 has a second nominal code rate R2, and a third LDPC encoder 506 has a third nominal code rate R3. Thus, in this example, the effective code rate (R_new) is the product of the code rates of all encoders: R_new=R1*R2*R3.

In some cases, challenges may arise when leverage existing codes, due to the input and output sizes of encoders being fixed for each code rate and nominal codeword size combination. For example, assuming nominal rates of ½, ⅔, ¾, ⅚ LDPC codes, a reduced nominal code rate of ⅓ may be achieved using rate ½ and rate ⅔, where the input/output sizes of the encoders, as labeled in FIG. 5, are: N_1=648, N_2=1296, and N_3=1944; while a reduced nominal code rate of ⅙ may be achieved using concatenated rates ½, ⅔, and ½, where N_1=648, N_2=1296, N_3=1944, N_4=3888. In such cases, a new nominal codeword size may remain as an existing nominal codeword size (e.g., N_3=1944 in rate ⅓ and N_4=3888 in rate ⅙, respectively).

To generalize this approach, however, to achieve more low code rates, the target code rate R where R<½ may constructed by the concatenation of multiple LDPC encoders with existing LDPC rate ½, ⅔, ¾, ⅚, and each encoder (e.g., the i-th encoder) may be combined with shortening and puncturing/repetition to keep same code rate R_i yet use a different set of input and output sizes (N_i, N_{i+1}). As an example, to achieve a reduced code rate of ¼ a concatenation of rate ½ and rate ½ may be used, where N_1=648 and N_2=1296. In this case, the input to the 2nd encoder may use 1944-1296-648 shortening bits and output from the 2nd encoder may have 3888 bits, where the transmitter may discard the 648 shortening bits and puncture 648 parity bits, resulting in N_3=2592. In this example scenario, the new nominal codeword size is a new size, 2592.

This approach provides flexibility to achieve a wide range of reduced nominal code rates. As examples, a code rate of ⅓ may be achieved by concatenating code rates of ½ and ⅔; a code rate of ¼ may be achieved by concatenating code rates of ½ and ½; a code rate of ⅙ may be achieved by concatenating code rates of ½, ½, and ⅔; a code rate of ⅛ may be achieved by concatenating code rates of ½, ½, and ½; a code rate of 1/9 may be achieved by concatenating code rates of ½, ½, ⅔, and ⅔; a code rate of 1/12 may be achieved by concatenating code rates of ½, ½, ½, and ⅔; a code rate of 1/16 may be achieved by concatenating code rates of ½, ½, ½, and ½.

A third method to achieve a reduced nominal code rate may utilize an encoder that utilizes padding bits, which may also be referred to as extended shortening bits.

According to this approach, as will be described in greater detail below with reference to FIG. 6, partial input bits input to the encoder may be known padding bits (with values known) to both the Tx and Rx nodes. For example, these known padding bits could be zero bits, all one bits, or a known sequence. On the Tx side, the transmitter may discard the padding bits at the LDPC output and not transmit them. On the Rx side, the receiver may supplement the log likelihood ratios (LLRs) of the known padding bits for decoder input and discard the corresponding bits at the decoder output.

FIG. 6 shows an example diagram 600 of how an encoder with extended shortening/padding bits may be used to achieve a reduced code rate. The illustrated example assumes an LDPC encoder (for a codeword) with a nominal CW size of 1944. In the illustrated example, known padding bits 604 are (486) zero bits and are appended to (486) information bits 602 prior to encoding using a nominal coding Rate-½. The encoding results in (972) parity bits 606. As illustrated, prior to transmission, the padding bits 604 are removed, leaving the information bits and parity bits.

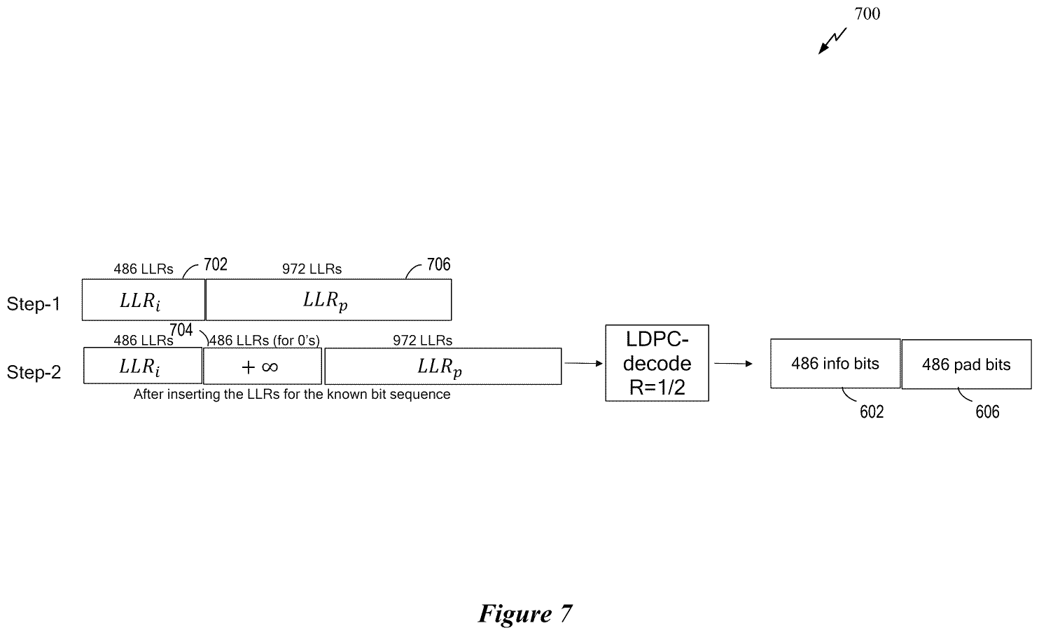

As illustrated in FIG. 7, on the receiver side, the receiver may generate LLRs 702 and 706 for the information bits and parity bits, respectively. The receiver may insert LLRs 704 for the known bit sequence. Utilizing a decoder of nominal rate ½, the receiver may then obtain the information bits 602 and padding bits 606.

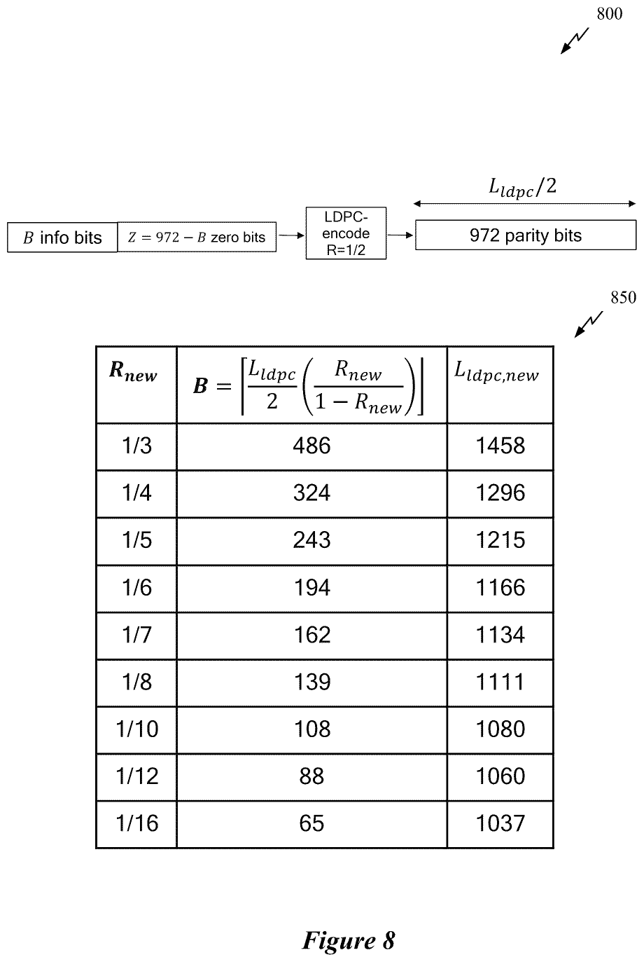

In this manner, the LDPC encoder may achieve a new nominal coding Rate R_{new}<½, using the nominal coding Rate-½. As noted above, this approach can be generalized to achieve various lower code rates (e.g., R_{new}=⅓, ¼, ⅛, 1/12, 1/16 . . . ). In such cases, as illustrated in diagram 800 of FIG. 8, the parity bit length may be fixed as L_{ldpc}/2, where L_{ldpc} is a nominal CW size. This may involve fixing the information bit length B, where B may be determined by solving:

$$\frac{B}{B + ( {L}_{ldpc} / 2 )} = {R}_{new} ,$$

As indicated in table 850 of FIG. 8, B may be expressed as:

$$B = ⌈ \frac{{L}_{ldpc}}{2} ( \frac{{R}_{new}}{1 - {R}_{new}} ) ⌋ ,$$

where round( ), floor( ) or ceil( ) functions may be used to get an integer number for B. As illustrated in FIG. 8, the parity bits may have a fixed length of L_{ldpc}/2, where L_{ldpc} is a nominal codeword size. FIG. 8 illustrates an example where L_{ldpc}=1944 and the parity bits, thus, have a fixed length of 972.

As indicated, Length-B may include both “payload bits” and “shortening bits” where the known bit sequence (e.g. Zero-bits) length

$$Z = \frac{{L}_{ldpc}}{2} - B$$

in order to attain fixed parity bits length of L_{ldpc}/2. In some cases, this may be viewed as longer shortening bits in hardware implementation.

The new LDPC length

$$( {L}_{ldpc , new} = \frac{{L}_{ldpc}}{2} + B )$$

may be used to determine the number of codewords N_{CW}, number of shortening bits Nₛₕᵣₜ, and number of puncturing bits N_{punc}. As indicated in the table 850 of FIG. 8, encoding parameter calculations related to the original nominal L_{ldpc} and R=½ may be adjusted, based on the new rate (R_{new}) and new nominal codeword size (L_{ldpc,new}).

Combinations of the various methods to achieve a reduced nominal code rate are also possible.

For example, a combination of the first and second methods may involve concatenated codes, followed by repetition. As an example, a code rate of ⅙ may be achieved using concatenated code rates of ½ and ⅔, followed by 2× repetition (N=2); a code rate of 1/12 may be achieved using concatenated code rates of ½ and ⅔, followed by 4× repetition (N=2).

As another example, a combination of the second and third methods may involve concatenated codes and/or an encoder using extended shortening bits. Using this approach, a reduced rate of ⅙ may be obtained using a nominal coding rate of rate ½ and an extended shortening bit encoder with a rate of ⅓; a reduced rate of 1/12 may be obtained using a concatenation of nominal coding rates of rates ½ and ½ and an extended shortening bit encoder with a rate of ⅓.

As another example, a combination of the first and third methods may involve a lower rate LDPC code generated by extended shortening bits encoder, followed by repetition. For example, a rate of ⅙ may be achieved using an extended shortening bit encoder with a rate of ⅓ and 2× repetition (N=2); a rate of 1/12 may be achieved using an extended shortening bit encoder with a rate of ⅓ and 2× repetition (N=4).

As still another example, a combination of the first, second, and third methods may involve concatenated codes, a lower rate code generated by an encoder with extended shortening bits, followed by repetition. As an example, a reduced rate of 1/12 may be obtained using a nominal code rate of ½ concatenated with a rate ⅓ (achieved by an encoder with extended shortening bits), and 2× repetition (N=2).

Various rate LDPC rate matching processes may be applied for the ELR Mode. For example, such rate matching may be applicable to the various methods proposed herein to achieve reduced nominal code rates for the ELR mode.

As described above, the nominal codeword size and nominal code rate may be changed due to new low rate LDPC design. Assuming an original nominal code rate R is from the set of {½, ⅔, ¾, ⅚}, original nominal codeword sizes L_{ldpc} are from the set of nominal codeword sizes {648, 1296, 1944, 3888}. In the ELR mode, a new nominal code rate

$${R}_{new} < \frac{1}{2} ,$$

a the new nominal codeword size is denoted as L_{ldpc,new} as described above. In some cases, a codeword size scaling factor b may be defined as:

$$b = \frac{{L}_{ldpc , new}}{{L}_{ldpc}} .$$

In case a new generic low rate LDPC design is used, the nominal codeword size may not change (e.g., corresponding to b=1).

If repetition is used to obtain reduced nominal code rates, the nominal codeword size may be N times the original nominal codeword size due to N times of repetition (e.g., b=N). If nominal rate codes are concatenated or an encoder using extended shortening bits is used to achieve reduced nominal code rates, the scaling factor may depend on the new nominal code rate R_{new} and may not be an integer number.

The LDPC rate matching for the ELR mode may use a rate matching algorithm that is similar to an existing (e.g., 802.11 be) rate matching algorithm, but with certain modifications.

First, basic parameters may be adjusted. For example, the number of coded bits for user u, N_{CBPS,u} and N_{CBPS,short,u}, may be adjusted if the QAM modulation and/or the effective number of data tones carrying unique data is changed. The number of data bits for user u, N_{DBPS,u} and N_{DBPS,short,u}, may be recalculated based on N_{CBPS,u} and N_{CBPS,short,u}, respectively, and the new nominal code rate R_{new}.

Second, the original nominal code rate R may be replaced by the new nominal code rate R_{new}. Third, the original nominal codeword sizes L_{ldpc} is replaced by the new nominal codeword size L_{ldpc,new}. Fourth, to select the codeword size and number of codewords (e.g., in the second rate matching step noted above), the conditions to obtain encoding parameters (e.g., from Table 1) may be adjusted according to the codeword size scaling factor b, since the nominal codeword size is changed. For example, the condition on range of N_{avbits} may be changed from C₁<N_{avbits}≤C₂ to bC₁<N_{avbits}≤bC₂ and the condition N_{avbits}≥N_{pld}+M×(1−R) may be changed to N_{avbits}≥N_{pld}+bM×(1−R).

If repetition is used, in addition to the above changes, other changes may be made. First, due to the nature of repetition, given N repetitions, the number of shortening bits per codeword must be a multiple of N. In Step 3 (shortening), change the total number of shortening bits to:

$${N}_{shrt , u} = max ( 0 , N \times ceil ( \frac{{N}_{CW , u} \cdot {L}_{LDPC , u} \cdot {R}_{u} - {N}_{pld , u}}{N} ) ) .$$

When N_{shrt,u}=0, thus, shortening is not performed. When N_{shrt,u}>0, shortening bits may be equally distributed over all N_{CW,u} codewords according to groups of N bits, with the first rem

$$( \frac{{N}_{shrt , u}}{N} , {N}_{CW , u} )$$

codewords being shortened N bit more than the remaining codewords. As described above, shortening bits may be appended after data bits (and discarded after encoding). The number of shortening bits per codeword before repetition may be 1/N of the number of shortening bits per codeword after repetition (e.g., the number of shorting bits will also be repeated N times).

Second, for puncturing and/or repetition (e.g., per the fourth rate matching step described above), the total number of puncturing bits and the total number of repeated bits may still calculated based on the same equations (e.g., as in 11be), but the punctured bits and repeated bits may be chosen differently. It may be noted that the number of puncturing bits per codeword and the number of repeated bits per codeword do not need to be multiples of N.

Regarding puncturing, when N_{punc,u}=0, puncturing is not performed. When N_{punc,u}>0, puncturing bits may be equally distributed over all N_{CW,u} codewords with the first rem (N_{punc,u}, N_{CW,u}) codewords being punctured one bit more than the remaining codewords. Generally, only parity bits may be punctured. Due to the nature of repetition, before puncturing, each parity bit has N copies. In some cases, the puncturing step can choose to puncture all copies of certain parity bits (usually puncturing happens from the last parity bit and goes backward). In other cases, the puncturing step may puncture duplicated parity bits (due to the method of repetition) while keeping at least one copy for each parity bit.

Regarding repetition, when N_{rep,u}=0, repetition is not performed. When N_{rep,u}>0, the number of coded bits to be repeated may be equally distributed over all N_{CW,u} codewords with one more bit repeated for the first rem (N_{rep,u},N_{CW,u}) codewords than the remaining codewords. The coded bits to be repeated for any codeword may be copied only from that codeword itself, starting from the beginning of that LDPC codeword (beginning of data bits). The repetition step can choose to repeat all copies of certain data bits (beginning of data bits of each copy) or, in some cases, may repeat as many as different distinct data bits as possible.

Techniques proposed herein may also be used to achieve reduced code rates for binary convolutional encoder (BCC) encoding. In some cases (e.g., 802.11be) a DATA field may support channel coding with BCC of coding rate R=½, ⅔, ¾, ⅚. The BCC of R=½ is generated by industry-standard generator polynomials, g₀=133₈ and g₁=171₈. The BCC of R=⅔, ¾, ⅚ may be derived from the BCC of R=½ by employing “puncturing”.

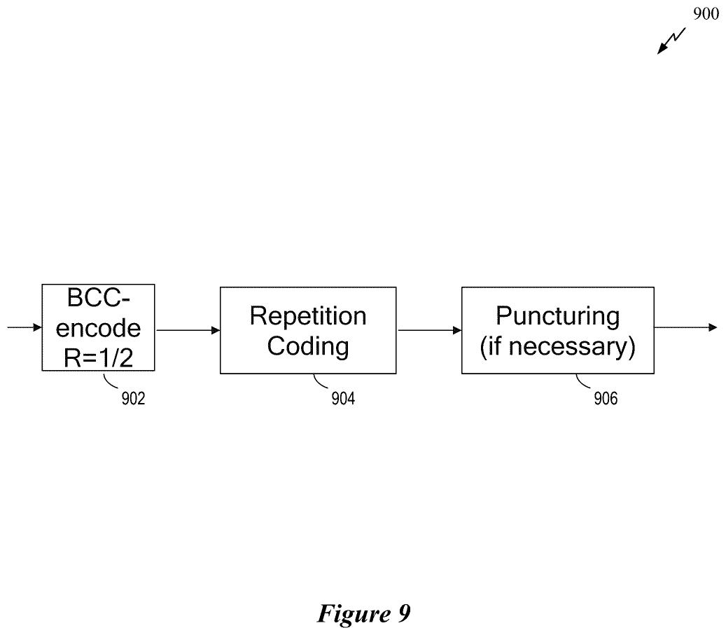

Aspects of the present disclosure may be used to achieve BCC of reduced code rate (e.g., R<½). For example, as illustrated in FIG. 9, a reduced rate may be achieved using a BCC encoder 902 of rate with repetition (as indicated at 904) and (in some cases) puncturing (as indicated at 906). In the illustrated example, a transmitter may first generate BCC of rate ½, and then perform repetition coding and puncturing (if necessary) to achieve a target lower code rate.

Examples that may not involve puncturing include reduced rates of ¼, ⅙, ⅛, 1/10, 1/12, and 1/16 obtained using Rate ½ BCC with 2×, 3×, 4×, 5×, 6×, and 8× repetition (N=2, N=3, N=4, N=5, N=6, and N=8,), respectively. Examples that may involve puncturing may include a reduced rate of ⅓ obtained using Rate ½ BCC with 2× repetition (N=2) and puncturing 1 bit out of every 4 bits; and a reduced rate of ⅕ obtained using Rate ½ BCC with 3× repetition (N=3) and puncturing 1 bit out of every 6 bits.

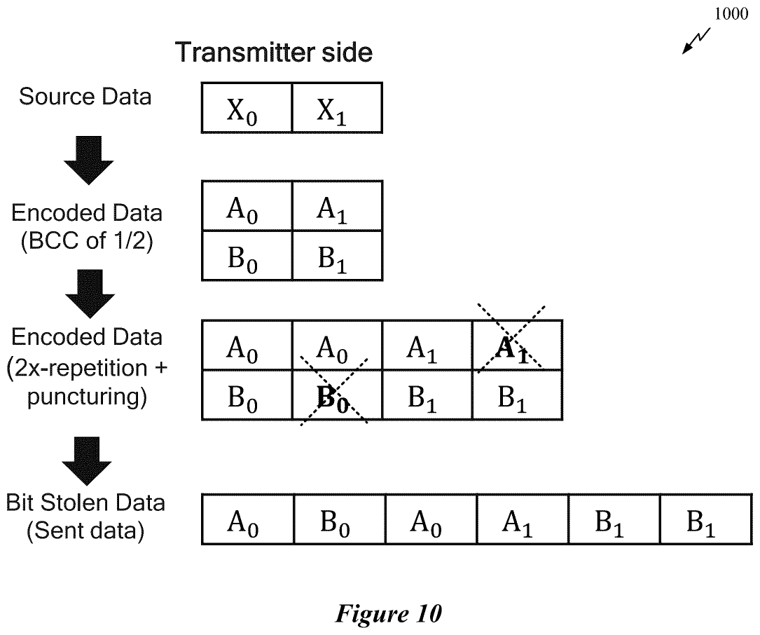

FIG. 10 illustrates an example of a transmitter achieving a reduced BCC rate of ⅓ using a BCC of rate ½, 2×-repetition, and puncturing 1 bit out of every 4 bits. In the illustrated example, a “Per 2-bit group repetition” is used as an example. Repetition patterns, however, can be implemented in different variations, e.g., “Per-bit repetition” (e.g., A0, A0, B0, B0, A1, A1, B1, B1, . . . ).

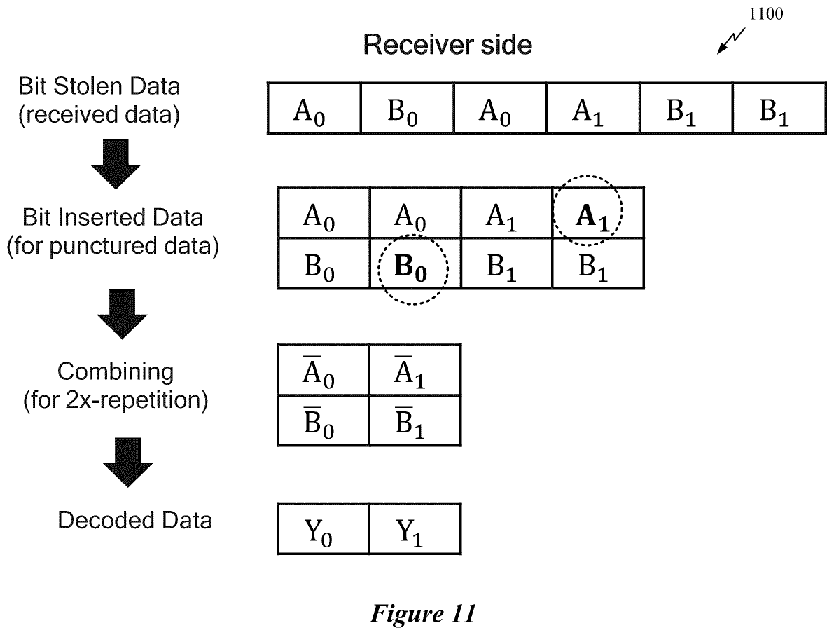

In the illustrate example, as indicated by the Xs, bits (B0, A1) are punctured iteratively every 8 bits. Thus, in this example, after repetition and puncturing the bits actually sent are “A0, B0, A0, A1, B1, B1”. Of course, a puncturing pattern can be implemented in different variations, for example, puncturing iteratively on (A0, B1) or (A0, B0) or (A1, B1). FIG. 11 illustrates an example of receiver-side processing corresponding to the example in FIG. 10. As shown, at the receiver side, bits are inserted corresponding to the punctured data and combining is performed to account for the repetition, finally resulting in decoded data.

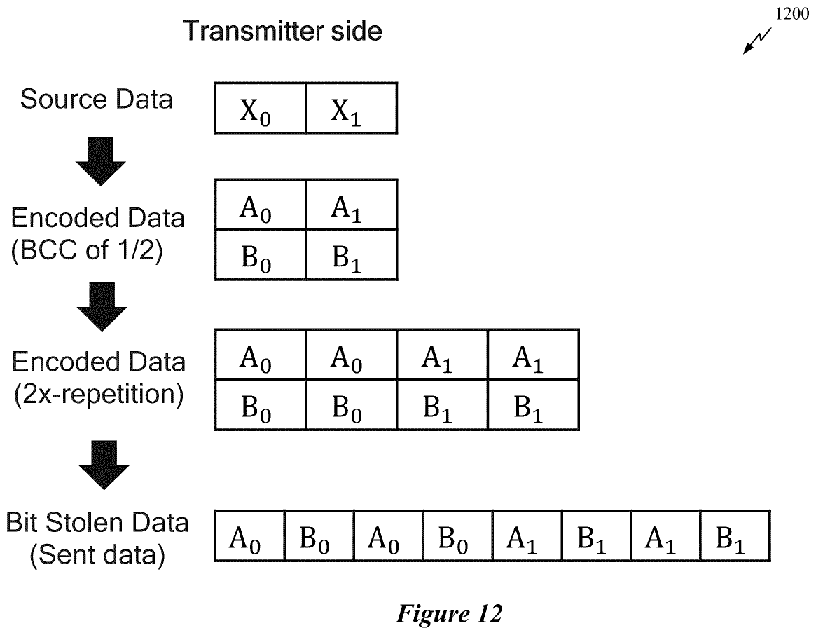

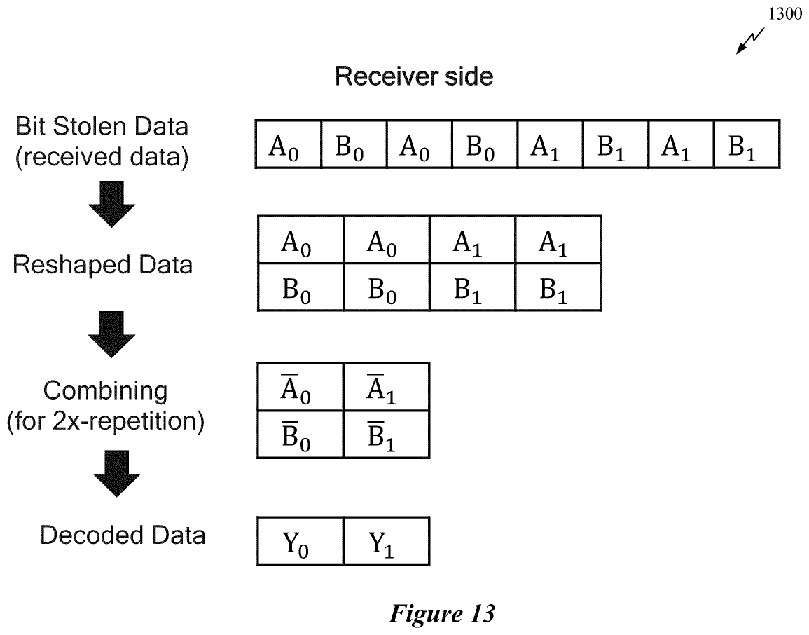

FIG. 12 illustrates an example of a transmitter achieving a reduced BCC rate of ¼ using a BCC of rate ½, and 2×-repetition, with no puncturing. In the illustrated example, a “Per 2-bit group repetition.” Without puncturing, the bits sent are “A0, B0, A0, B0, A1, B1, A1, B1.” FIG. 13 illustrates an example of receiver-side processing corresponding to the example in FIG. 11. As shown, at the receiver side, after reshaping the data, combining is performed to account for the repetition, finally resulting in decoded data.

BCC rate matching for the ELR mode may reuse an existing (e.g., 802.11be) BCC rate matching algorithm, but with various changes. First, basic parameters may be adjusted, in a similar manner as described above with reference to the LDPC rate matching for the ELR mode. Second, the original nominal code rate R (e.g., ½, ⅔, ¾, ⅚) may replaced by the new nominal code rate R_new (e.g., ⅓, ⅙, 1/16). The parameters related to the number coded bits, N_{CBPS} and N_{CBPS,short}, and the number of data bits, N_{DBPS} and N_{DBPS,short} need to be adjusted according to new nominal code rate R_new.

The BCC rate matching is different from the LDPC rate matching for various reasons. For example, BCC encoding is not block code based and, thus, it may be easier to fit data bits within the pre-FEC padding boundary and easier to fit coded bits within the PHY coded bits boundary. BCC rate matching may also not have further puncturing and, as described above, may only use repetition to reach the PHY coded bits boundary. In BCC rate matching, the pre-FEC padding boundary and PHY coded bits boundary may be the same.

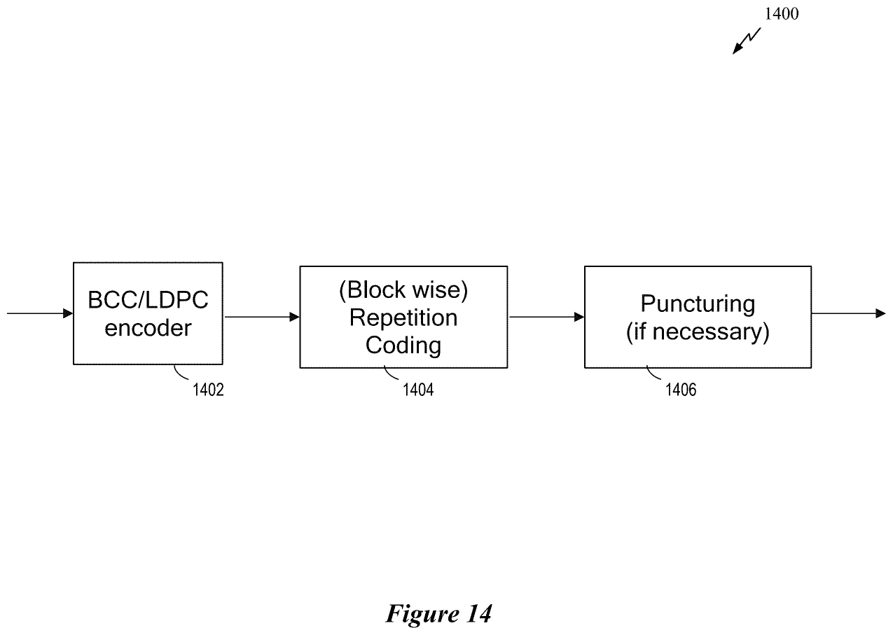

In some cases, the repetition of coded bits may increase signal peak to average power ratio (PAPR), which can be mitigated by applying a mask or scrambling sequence. This may be applied, for example, in a transmitter scenario 1400 shown in FIG. 14, where an encoder 1402 (e.g., BCC or LDPC) is followed by repetition (at 1404) and possible puncturing (at 1406).

According to a first option to mitigate PAPR, a mask may be applied to the duplicated coded bits to break the repetition pattern. This may be understood by considering an example that assumes a block wise repetition (as shown at 1404 in FIG. 14) with coded bits block size L=8. It may be assumed that [C1 . . . . C8] is the 8 original coded bits in an OFDM symbol. The output bit stream after 4× repetition is a 32-bits sequence:

$$Cout = [ [ C 1 ... . C 8 ] , [ C 1 ... . C 8 , C 1 ... . C 8 , C 1 ... . C 8 ] ] XOR S 32 ,$$

where S32 is some length-32 scrambling sequence to reduce PAPR, consisting of 0s and 1s. The output bit stream after 8× repetition is a 64-bits sequence:

$$Cout = [ [ C 1 ... . C 8 ] , [ C 1 ... . C 8 , C 1 ... . C 8 , C 1 ... . C 8 , \\ C 1 ... . C 8 , C 1 ... . C 8 , C 1 ... . C 8 , C 1 ... . C 8 ] ] XOR S 64 ,$$

where S64 is some length-64 scrambling sequence to reduce PAPR, consisting of bit values of 0s and 1s.

In some cases, scrambling sequence S32 and S64 can be optimized to minimize PAPR statistics or can be some KNOWN sequence that is known to both transmitter and receiver and good for PAPR reduction.

In some cases, a scrambling sequence may be taken from an existing scrambling sequence. The scrambling sequence may have a fixed initial value (e.g., across different packets) or different initial values for different packets. In the case of different values for different packets, the value may be the same initial value for the scrambling of the data field of the packet (which is random and signaled in the SERVICE field). In some cases, a scrambling sequence may be taken from an existing (e.g., 802.11a to 802.11ax) data scrambling sequence that is defined by generator polynomial of S(x)=x⁷+x⁴+1, with a fixed 7 initial bits (e.g. all 1s). S32 can be the first 32 bits generated from this scrambler, similarly for S64, S16 (for 2× repetition), or S48 (for 6× repetition). As another example, a scrambling sequence may be taken from an existing (e.g., 802.11be) data scrambling sequence that is defined by generator polynomial of S (x)=x¹¹+x⁹+1, with a fixed 11 initial bits (e.g. all 1s). S32 can be the first 32 bits generated from this scrambler, similarly for S64,S16 (for 2× repetition), and S48 (for 6× repetition). These examples may be generalized to any coded bits block size L and any number of repetitions, by making use of fixed existing scrambling sequence defined for data.

According to a first option to mitigate PAPR, a mask may be applied to the data tones of each OFDM symbol, after constellation mapping. For example, existing (e.g., 802.11be) 20 MHz symbols may have 242 tones, in which there are 8 pilots and 234 data tones. In such cases, the duplicated coded bits assigned to each OFDM symbol may be mapped to QAM symbols (one QAM symbol on each data tone). A known mask may be applied to the data tones to help reduce PAPR, for example, using the HE-LTF or EHT-LTF defined for 20 MHz (e.g., using the LTF values on data tones for masking). This approach may be considered as similar in effect to performing per data tone rotation to reduce PAPR.

Some processes, methods, operations, techniques or other aspects described herein may be implemented, at least in part, using an artificial intelligence (AI) program, such as a program that includes a machine learning (ML) or artificial neural network (ANN) model, hereinafter referred to generally as an AI/ML model. One or more AI/ML models may be implemented in wireless communication devices (for example, APs 102 and STAs 104) and to enhance various aspects associated with wireless communication. For example, an AI/ML model may be trained to identify patterns or relationships in data observed in a wireless communication network 100. An AI/ML model may support operational decisions relating to aspects associated with wireless communications networks or services. For example, an AI/ML model may be utilized for supporting or improving aspects such as reducing signaling overhead (such as by CSI feedback compression, etc.), enhancing roaming or other mobility operations, multi-AP coordination, and generally facilitating network management or optimizing network connections or characteristics to, for example, increase throughput or capacity, reduce latency or otherwise enhance user experience.

An example AI/ML model may include mathematical representations or define computing capabilities for making inferences from input data based on patterns or relationships identified in the input data. As used herein, the term “inferences” can include one or more of decisions, predictions, determinations, or values, which may represent outputs of the AI/ML model. The computing capabilities may be defined in terms of certain parameters of the AI/ML model, such as weights and biases. Weights may indicate relationships between certain input data and certain outputs of the AI/ML model, and biases are offsets that may indicate a starting point for outputs of the AI/ML model. An example AI/ML model operating on input data may start at an initial output based on the biases and then update the output based on a combination of the input data and the weights.

STAs or APs (for example, a STA 104 or an AP 102) may exchange local observations with other wireless communication devices (such as other STAs or APs) or provide feedback related to the communication. This may significantly expand the types of input data that can be considered as input to an AI/ML model, as such information may not otherwise be available at the other wireless communication devices. For example, information received from other STAs or APs may include observed RSSI values, experienced packet success/failure/retry rates per client/AP, BSS/Quality of Service (QoS) load/requirements, or a history of bad/good AP link(s), which may be conveyed in terms of scores or rankings.

AI/ML models can be centralized, distributed, or federated. As both STAs 104 and APs 102 can participate in AI/ML based operations, efficient AI/ML model distribution may enhance the performance of a wireless communication system. In some examples supporting centralized AI/ML models, STAs 104 may provide training data to a centralized network location (such as an AP, AP MLD, or a server) where a global AI/ML model may be generated and refined. The centralized network location may distribute the global AI/ML model to various STAs. In some examples, global AI/ML models may train a single classifier based on all training data received from various inputs/sources. In some examples supporting distributed learning or distributed models, both APs and STAs may be independently capable of computing AI/ML models and sharing data with other participating wireless communication devices in the wireless communication network such that each device can train the global AI/ML model locally. In some examples supporting a federated learning or hybrid AI/ML model, substantially all participating wireless communication devices (such as AP 102s and STA 104s) may be capable of generating local AI/ML models and sharing their local models to a centralized network location or entity. In turn, the centralized network entity may generate a global AI/ML model using the received local models as input and distribute the global model to all or a subset of the participating wireless communication devices.

In some examples, AI/ML models may be downloadable. For example, an AP may share AI/ML model components with associated STAs or other friendly/coordinating APs. STAs may download the AI/ML model and use the model for making decisions related to wireless communications. The downloading of an AI/ML model may be independent from signaling the inputs to the AI/ML model (for example, some wireless communication devices may download the AI/ML model without exchanging information with other wireless communication devices; some wireless communication devices may exchange information and use such information as an input to the AI/ML model without downloading it; and some wireless communication devices may download the AI/ML model and exchange information or the AI/ML model with other wireless communication devices).

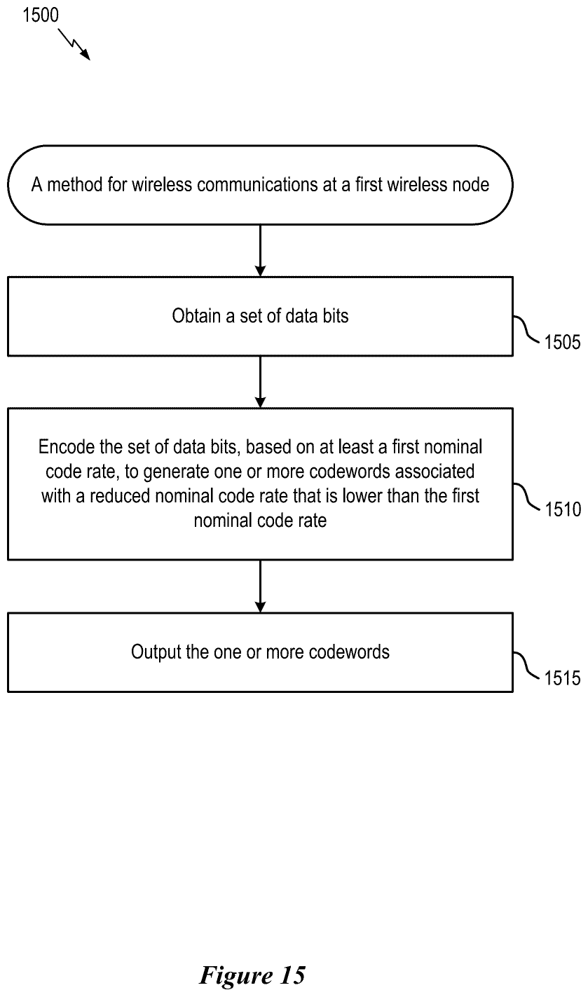

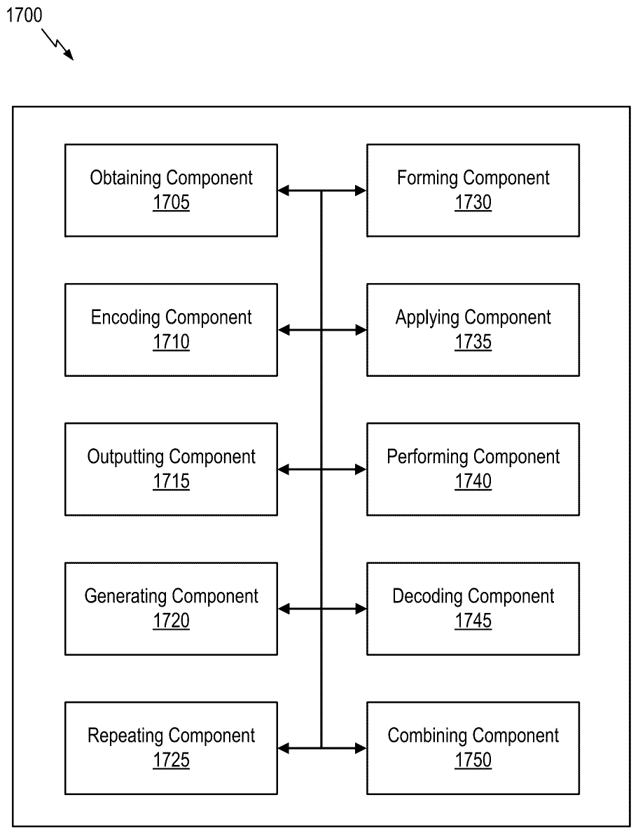

FIG. 15 shows a flowchart illustrating an example process 1500 performable by or at a first wireless node that supports low rate coding proposed herein. The operations of the process 1500 may be implemented by a wireless AP, or its components as described herein, or by a wireless STA or its components as described herein. For example, the process 1500 may be performed by a wireless communication device, such as the wireless communication device 1700 described with reference to FIG. 17, operating as or within a wireless AP and/or a wireless STA. In some examples, the process 1500 may be performed by a wireless AP such as one of the APs 102 described with reference to FIG. 1. In some examples, the process 1500 may be performed by a wireless STA such as one of the STAs 104 described with reference to FIG. 1.

Process 1500 begins at block 1505 with obtaining a set of data bits. In some cases, the operations of this block refer to, or may be performed by, circuitry for obtaining and/or code for obtaining as described with reference to FIG. 17.

Process 1500 then proceeds to block 1510 with encoding the set of data bits, based on at least a first nominal code rate, to generate one or more codewords associated with a reduced nominal code rate that is lower than the first nominal code rate. In some cases, the operations of this block refer to, or may be performed by, circuitry for encoding and/or code for encoding as described with reference to FIG. 17.

Process 1500 then proceeds to block 1515 with outputting the one or more codewords. In some cases, the operations of this block refer to, or may be performed by, circuitry for outputting and/or code for outputting as described with reference to FIG. 17.

In some aspects, the encoding involves at least one of: LDPC encoding; or BCC encoding.

In some aspects, the encoding comprises: generating first codewords; and repeating coded bits of the first codewords to generate second codewords that comprise the one or more codewords.

In some aspects, the repetition comprises repeating the coded bits of the first codewords N times; the size of one of the second codewords is N times the size of one of the first codewords; and the reduced nominal code rate is (1/N) of the first nominal code rate.

In some aspects, a quantity of shortening bits in each of the second codewords is a multiple of N.

In some aspects, generating first codewords comprises: encoding the set of data bits based on the first nominal code rate to obtain first coded bits; and encoding the first coded bits based on a second nominal code rate to obtain the first codewords.

In some aspects, generating first codewords comprises: forming a set of systematic bits by appending a set of padding bits to the set of data bits, encoding the systematic bits to generate parity bits, and generating the first codewords by appending the parity bits to the data bits.

In some aspects, the encoding comprises: generating first codewords; repeating coded bits associated with the first codewords to generate second codewords; and applying a mask sequence to the repeated coded bits within each of the second codewords to generate the one or more codewords.

In some aspects, the encoding comprises generating first codewords and repeating coded bits associated with the first codewords to generate second codewords; and the process 1500 further comprises performing constellation mapping of the repeated coded bits to generate OFDM symbols; and applying a mask sequence to data tones of the OFDM symbols.

In some aspects, the encoding comprises: encoding the set of data bits based on the first nominal code rate to generate first codewords; and further encoding the first codewords based on at least a second nominal code rate to generate third codewords that have the reduced code rate that is a function of at least the first code rate and the second code rate.

In some aspects, the process 1500 further includes forming a set of systematic bits by appending a set of padding bits to the set of data bits prior to the encoding, encoding the systematic bits based on the first nominal code rate to generate the first codewords and further encoding the first codewords based on the second nominal code rate to generate the third codewords. In some cases, the operations of this block refer to, or may be performed by, circuitry for forming and/or code for forming as described with reference to FIG. 17.

In some aspects, at least one encoder used for the further encoding performs at least one of a fixed quantity of puncturing of parity bits or a fixed quantity of repetition of data bits to achieve a target nominal code rate and a nominal codeword size of second codewords.

In some aspects, the process 1500 further includes forming a set of systematic bits by appending a set of padding bits to the set of data bits, wherein the encoding comprises encoding the systematic bits to generate first codewords of a first size with parity bits, and generating second codewords of a second size with the data bits and parity bits. In some cases, the operations of this block refer to, or may be performed by, circuitry for forming and/or code for forming as described with reference to FIG. 17.

In some aspects, a length of the data bits in each of the second codewords is a function of the reduced code rate and a nominal codeword size of the first codewords.

In some aspects, a length of the padding bits in each of the second codewords is a function of the length of the data bits in each of the second codewords and the nominal codeword size of the first codewords.

In some aspects, a size of the one or more second codewords is a function of the length of the data bits in each of the second codewords and the nominal codeword size of the first codewords.

In some aspects, at least one of: a nominal codeword size is adjusted based on the nominal codeword size of the second codewords; or at least one of a number coded bits, a number of shortening bits, or a number of data bits is adjusted based on the reduced code rate.

Note that FIG. 15 is just one example of a process, and other processes including fewer, additional, or alternative blocks are possible consistent with this disclosure.

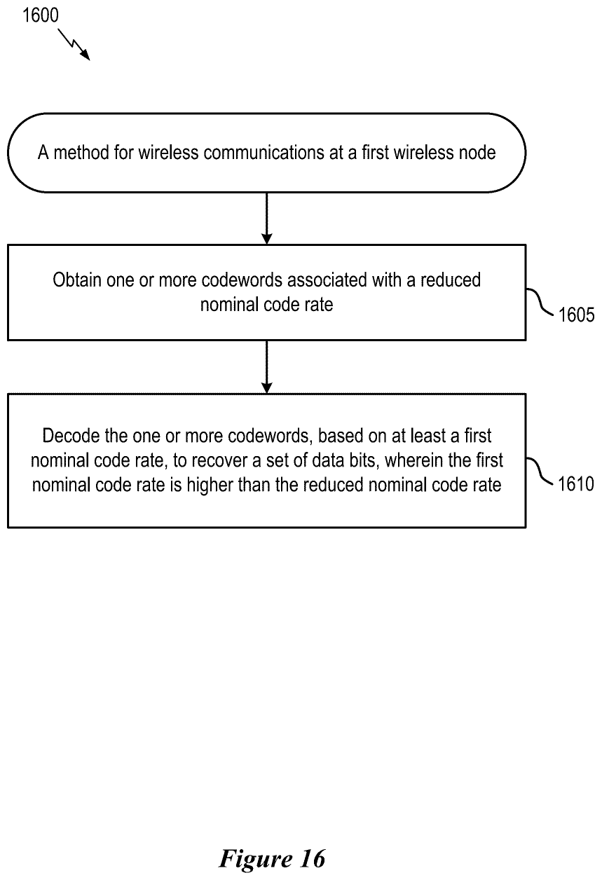

FIG. 16 shows a flowchart illustrating an example process 1600 performable by or at a wireless STA that supports low rate coding proposed herein. The operations of the process 1600 may be implemented by a wireless AP, or its components as described herein, or by a wireless STA or its components as described herein. For example, the process 1600 may be performed by a wireless communication device, such as the wireless communication device 1700 described with reference to FIG. 17, operating as or within a wireless AP and/or a wireless STA. In some examples, the process 1600 may be performed by a wireless AP such as one of the APs 102 described with reference to FIG. 1. In some examples, the process 1600 may be performed by a wireless STA such as one of the STAs 104 described with reference to FIG. 1.

Process 1600 begins at block 1605 with obtaining one or more codewords associated with a reduced nominal code rate. In some cases, the operations of this block refer to, or may be performed by, circuitry for obtaining and/or code for obtaining as described with reference to FIG. 17.

Process 1600 then proceeds to block 1610 with decoding the one or more codewords, based on at least a first nominal code rate, to recover a set of data bits, wherein the first nominal code rate is higher than the reduced nominal code rate. In some cases, the operations of this block refer to, or may be performed by, circuitry for decoding and/or code for decoding as described with reference to FIG. 17.

In some aspects, the decoding involves at least one of: LDPC decoding; or BCC decoding.

In some aspects, the decoding comprises: decoding the one or more codewords; and combining decoded bits after the decoding.

In some aspects, the decoding comprises: decoding the one or more codewords based on the first nominal code rate to obtain first codewords; and decoding the first codewords based on a second nominal code rate.

In some aspects, the decoding comprises: decoding the one or more codewords to obtain a set of systematic bits that includes a set of padding bits appended to the set of data bits.

In some aspects, the decoding comprises: decoding the one or more codewords based on the first nominal code rate to obtain first codewords; and decoding the first codewords based on a second nominal code rate.

In some aspects, the decoding comprises: decoding the one or more codewords to obtain a set of systematic bits that includes a set of padding bits appended to the set of data bits.

In some aspects, a length of the padding bits is a function of the length of the data bits and the nominal codeword size of the first codewords.

In some aspects, a length of the data bits is a function of the reduced code rate and a nominal codeword size.

In some aspects, at least one of a nominal codeword size is adjusted based on the nominal codeword size of the second codewords; and at least one of a number coded bits, a number of shortening bits, or a number of data bits is adjusted based on the reduced code rate.

Note that FIG. 16 is just one example of a process, and other processes including fewer, additional, or alternative blocks are possible consistent with this disclosure.

FIG. 17 shows a block diagram of an example wireless communication device 1700 that supports low rate coding proposed herein. In some examples, the wireless communication device 1700 is configured to perform the process 1500 described with reference to FIG. 15. The wireless communication device 1700 may include one or more chips, SoCs, chipsets, packages, components or devices that individually or collectively constitute or comprise a processing system. The processing system may interface with other components of the wireless communication device 1700, and may generally process information (such as inputs or signals) received from such other components and output information (such as outputs or signals) to such other components. In some aspects, an example chip may include a processing system, a first interface to output or transmit information and a second interface to receive or obtain information. For example, the first interface may refer to an interface between the processing system of the chip and a transmission component, such that the device 1700 may transmit the information output from the chip. In such an example, the second interface may refer to an interface between the processing system of the chip and a reception component, such that the device 1700 may receive information that is then passed to the processing system. In some such examples, the first interface also may obtain information, such as from the transmission component, and the second interface also may output information, such as to the reception component.

The processing system of the wireless communication device 1700 includes processor (or “processing”) circuitry in the form of one or multiple processors, microprocessors, processing units (such as central processing units (CPUs), graphics processing units (GPUs) or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor” or “the processor circuitry”). One or more of the processors may be individually or collectively configurable or configured to perform various functions or operations described herein. The processing system may further include memory circuitry in the form of one or more memory devices, memory blocks, memory elements or other discrete gate or transistor logic or circuitry, each of which may include tangible storage media such as random-access memory (RAM) or read-only memory (ROM), or combinations thereof (all of which may be generally referred to herein individually as “memories” or collectively as “the memory” or “the memory circuitry”). One or more of the memories may be coupled with one or more of the processors and may individually or collectively store processor-executable code that, when executed by one or more of the processors, may configure one or more of the processors to perform various functions or operations described herein. Additionally or alternatively, in some examples, one or more of the processors may be preconfigured to perform various functions or operations described herein without requiring configuration by software. The processing system may further include or be coupled with one or more modems (such as a Wi-Fi (for example, IEEE compliant) modem or a cellular (for example, 3GPP 4G LTE, 5G or 6G compliant) modem). In some implementations, one or more processors of the processing system include or implement one or more of the modems. The processing system may further include or be coupled with multiple radios (collectively “the radio”), multiple RF chains or multiple transceivers, each of which may in turn be coupled with one or more of multiple antennas. In some implementations, one or more processors of the processing system include or implement one or more of the radios, RF chains or transceivers.

In some examples, the wireless communication device 1700 can be configurable or configured for use in an AP, such as the AP 102 described with reference to FIG. 1. In some other examples, the wireless communication device 1700 can be an AP that includes such a processing system and other components including multiple antennas. In some examples, the wireless communication device 1700 can be configurable or configured for use in a STA, such as the STA 104 described with reference to FIG. 1. In some other examples, the wireless communication device 1700 can be a STA that includes such a processing system and other components including multiple antennas. The wireless communication device 1700 is capable of transmitting and receiving wireless communications in the form of, for example, wireless packets. For example, the wireless communication device 1700 can be configurable or configured to transmit and receive packets in the form of physical layer PPDUs and MPDUs conforming to one or more of the IEEE 802.11 family of wireless communication protocol standards. In some other examples, the wireless communication device 1700 can be configurable or configured to transmit and receive signals and communications conforming to one or more 3GPP specifications including those for 5G NR or 6G. In some examples, the wireless communication device 1700 also includes or can be coupled with one or more application processors which may be further coupled with one or more other memories. In some examples, the wireless communication device 1700 further includes at least one external network interface coupled with the processing system that enables communication with a core network or backhaul network that enables the wireless communication device 1700 to gain access to external networks including the Internet.

The wireless communication device 1700 includes an obtaining component 1705, an encoding component 1710, an outputting component 1715, a generating component 1720, a repeating component 1725, a forming component 1730, an applying component 1735, a performing component 1740, a decoding component 1745, and a combining component 1750. Portions of one or more of the components 1705, 1710, 1715, 1720, 1725, 1730, 1735, 1740, 1745, and 1750 may be implemented at least in part in hardware or firmware. For example, the obtaining component 1705 may be implemented at least in part by a processor or a modem. In some examples, portions of one or more of the components 1705, 1710, 1715, 1720, 1725, 1730, 1735, 1740, 1745, and 1750 may be implemented at least in part by a processor and software in the form of processor-executable code stored in a memory.

In some cases, rather than actually transmitting, for example, signals and/or data, the wireless communication device 1700 may have an interface to output or provide signals and/or data for transmission (means for outputting or means for providing). For example, a processor may output signals and/or data, via a bus interface, to a radio frequency (RF) front end of the wireless communication device 1400 for transmission. In various aspects, the RF front end may include various components, including transmit and receive processors, transmit and receive MIMO processors, modulators, demodulators, and the like.

In some cases, rather than actually receiving signals and/or data, the wireless communication device 1700 may have an interface to obtain the signals and/or data received from another device (means for obtaining). For example, a processor may obtain (or receive) the signals and/or data, via a bus interface, from an RF front end of the wireless communication device 1700 for reception. In various aspects, the RF front end may include various components, including transmit and receive processors, transmit and receive MIMO processors, modulators, demodulators, and the like. In various aspects, means for obtaining, means for encoding, means for adjusting, means for outputting, means for generating, means for repeating, means for puncturing, means for applying, means for performing, means for forming, and means for decoding may comprise one or more processors (such as the one or more processors/components illustrated in the figures and/or described above).

### EXAMPLE CLAUSES

Implementation examples are described in the following numbered clauses.
Clause 1: A method for wireless communications at a first wireless node, comprising: obtaining a set of data bits; encoding the data bits, based on at least a first nominal code rate, to generate one or more codewords associated with a reduced nominal code rate that is lower than the first nominal code rate; and outputting the one or more codewords.
Clause 2: The method of Clause 1, wherein the encoding involves at least one of: low density parity check (LDPC) encoding; or binary convolutional code (BCC) encoding.
Clause 3: The method of any one of Clauses 1-2, wherein the encoding comprises: generating first codewords comprising coded bits; and repeating the coded bits of the first codewords to generate second codewords, wherein the one or more codewords comprise the second codewords.
Clause 4: The method of Clause 3, wherein at least one of: the repetition comprises repeating the coded bits of the first codewords N times; the size of one of the second codewords is N times the size of one of the first codewords; or the reduced nominal code rate is (1/N) of the first nominal code rate.
Clause 5: The method of Clause 4, wherein a quantity of shortening bits in each of the second codewords is a multiple of N.
Clause 6: The method of Clause 3, wherein generating first codewords comprises: encoding the data bits based on the first nominal code rate to obtain first coded bits; and encoding the first coded bits based on a second nominal code rate to obtain the first codewords.
Clause 7: The method of Clause 3, wherein generating the first codewords comprises: forming systematic bits by appending padding bits to the data bits, encoding the systematic bits to generate parity bits, and appending the parity bits to the data bits to generate the first code words.
Clause 8: The method of any one of Clauses 1-7, wherein the encoding comprises: generating first codewords; repeating coded bits associated with the first codewords to generate second codewords; and applying a mask sequence to the repeated coded bits within each of the second codewords to generate the one or more codewords.
Clause 9: The method of Clause 8, wherein the mask sequence is based on a scrambling sequence.
Clause 10: The method of Clause 9, wherein an initial value of the scrambling sequence is a fixed value or a different value.
Clause 11: The method of any one of Clauses 1-10, wherein: the encoding comprises: generating first codewords comprising coded bits; and repeating the coded bits of the first codewords to generate second codewords; and the method further comprises: performing constellation mapping of the repeated coded bits to generate orthogonal frequency division multiplexing (OFDM) symbols; and applying a mask sequence to data tones of the OFDM symbols when outputting the one or more codewords.
Clause 12: The method of Clause 11, wherein the mask sequence is based on a sequence of values that comprise +1 and −1 values.
Clause 13: The method of Clause 12, wherein the mask sequence is based on a known sequence of +1 and −1 values.
Clause 14: The method of Clause 13, wherein the mask sequence is based on a known sequence used in a long training field (LTF).
Clause 15: The method of any one of Clauses 1-14, wherein the encoding comprises: encoding the set of data bits based on the first nominal code rate to generate first codewords; and further encoding the first codewords based on at least a second nominal code rate to generate second codewords that have the reduced nominal code rate that is a function of at least the first code rate and the second code rate, wherein the one or more codewords comprise the second codewords.
Clause 16: The method of Clause 15, comprising: forming a set of systematic bits by appending a set of padding bits to the set of data bits prior to the encoding, encoding the systematic bits based on the first nominal code rate to generate the first codewords and further encoding the first codewords based on the second nominal code rate to generate the second codewords.
Clause 17: The method of Clause 15, wherein the further encoding comprises performing at least one of a fixed quantity of puncturing of parity bits or a fixed quantity of repetition of data bits.
Clause 18: The method of any one of Clauses 1-17, comprising: forming systematic bits by appending padding bits to the data bits, wherein the encoding comprises encoding the systematic bits to generate first codewords of a first size with parity bits, and generating second codewords of a second size with the data bits and the parity bits, wherein the one or more codewords comprise the second codewords.
Clause 19: The method of Clause 18, wherein a length of the data bits in one of the second codewords is a function of the reduced nominal code rate and a nominal codeword size of the first codewords.
Clause 20: The method of Clause 19, wherein a length of the padding bits is a function of the length of the data bits in one of the second codewords and the nominal codeword size of the first codewords.
Clause 21: The method of Clause 19, wherein a size of the one or more second codewords is a function of the length of the data bits in each of the second codewords and the nominal codeword size of the first codewords.
Clause 22: The method of any one of Clauses 1-21, further comprising at least one of: adjusting a nominal codeword size based on a nominal codeword size of the second codewords; or adjusting at least one of a quantity of coded bits, a quantity of shortening bits, or a quantity of data bits based on the reduced nominal code rate.
Clause 23: A method for wireless communications at a first wireless node, comprising: obtaining one or more codewords associated with a reduced nominal code rate; and decoding the one or more codewords, based on at least a first nominal code rate, to recover a set of data bits, wherein the first nominal code rate is higher than the reduced nominal code rate.
Clause 24: The method of Clause 23, wherein the decoding involves at least one of: low density parity check (LDPC) decoding; or binary convolutional code (BCC) decoding.
Clause 25: The method of any one of Clauses 23-24, wherein the decoding comprises: decoding the one or more codewords; and combining decoded bits after the decoding.
Clause 26: The method of Clause 25, wherein the decoding comprises: decoding the one or more codewords based on the first nominal code rate to obtain first codewords; and decoding the first codewords based on a second nominal code rate.
Clause 27: The method of Clause 25, wherein the decoding comprises: decoding the one or more codewords to obtain a set of systematic bits that includes a set of padding bits appended to the set of data bits.
Clause 28: The method of any one of Clauses 23-27, wherein the decoding comprises: decoding the one or more codewords based on the first nominal code rate to obtain first codewords; and decoding the first codewords based on a second nominal code rate.
Clause 29: The method of Clause 28, wherein the decoding comprises: decoding the one or more codewords to obtain a set of systematic bits that includes a set of padding bits appended to the set of data bits.
Clause 30: The method of Clause 29, wherein a length of the padding bits is a function of the length of the data bits and the nominal codeword size of the first codewords.
Clause 31: The method of any one of Clauses 23-30, wherein a length of the data bits is a function of the reduced code rate and a nominal codeword size.
Clause 32: The method of any one of Clauses 23-31, wherein at least one of a nominal codeword size is adjusted based on the nominal codeword size of the second codewords; and at least one of a number coded bits, a number of shortening bits, or a number of data bits is adjusted based on the reduced code rate.
Clause 33: An apparatus, comprising: at least one memory comprising executable instructions; and at least one processor configured to execute the executable instructions and cause the apparatus to perform a method in accordance with any combination of Clauses 1-32.
Clause 34: An apparatus, comprising means for performing a method in accordance with any combination of Clauses 1-32.
Clause 35: A non-transitory computer-readable medium comprising executable instructions that, when executed by at least one processor of an apparatus, cause the apparatus to perform a method in accordance with any combination of Clauses 1-32.
Clause 36: A computer program product embodied on a computer-readable storage medium comprising code for performing a method in accordance with any combination of Clauses 1-32.
Clause 37: A wireless node comprising: at least one transceiver; at least one memory comprising executable instructions; and at least one processor configured to execute the executable instructions and cause the apparatus to perform a method in accordance with any combination of Clauses 1-22, wherein the at least one transceiver is configured to transmit the one or more codewords.
Clause 38: A wireless node comprising: at least one transceiver; at least one memory comprising executable instructions; and at least one processor configured to execute the executable instructions and cause the apparatus to perform a method in accordance with any combination of Clauses 23-32, wherein the at least one transceiver is configured to receive the one or more codewords.

### ADDITIONAL CONSIDERATIONS

As used herein, the term “determine” or “determining” encompasses a wide variety of actions and, therefore, “determining” can include calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

As used herein, a phrase referring to “at least one of” or “one or more of” a list of items refers to any combination of those items, including single members. As an example, “at least one of: a, b, or c” is intended to cover: a, b, c, a−b, a−c, b−c, and a−b−c. As used herein, “or” is intended to be interpreted in the inclusive sense, unless otherwise explicitly indicated. For example, “a or b” may include a only, b only, or a combination of a and b. Furthermore, as used herein, a phrase referring to “a” or “an” element refers to one or more of such elements acting individually or collectively to perform the recited function(s). Additionally, a “set” refers to one or more items, and a “subset” refers to less than a whole set, but non-empty.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein, but are to be accorded the widest scope consistent with this disclosure, the principles and the novel features disclosed herein.

Additionally, various features that are described in this specification in the context of separate examples also can be implemented in combination in a single implementation. Conversely, various features that are described in the context of a single implementation also can be implemented in multiple examples separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together in a single software product or packaged into multiple software products.

What is claimed is:

1. An apparatus for wireless communication, comprising:
at least one memory comprising computer-executable instructions; and
one or more processors configured to execute the computer-executable instructions and cause the apparatus to:
obtain a set of data bits;
encode the data bits, based on at least a first nominal code rate, to generate one or more codewords associated with a reduced nominal code rate that is lower than the first nominal code rate; and
output the one or more codewords.

2. The apparatus of claim 1, wherein the encoding involves at least one of:
low density parity check (LDPC) encoding; or
binary convolutional code (BCC) encoding.

3. The apparatus of claim 1, wherein the encoding comprises:
generating first codewords comprising coded bits; and
repeating the coded bits of the first codewords to generate second codewords, wherein the one or more codewords comprise the second codewords.

4. The apparatus of claim 3, wherein at least one of:
the repetition comprises repeating the coded bits of the first codewords N times;
the size of one of the second codewords is N times the size of one of the first codewords; or
the reduced nominal code rate is (1/N) of the first nominal code rate.

5. The apparatus of claim 4, wherein a quantity of shortening bits in each of the second codewords is a multiple of N.

6. The apparatus of claim 3, wherein generating first codewords comprises:
encoding the data bits based on the first nominal code rate to obtain first coded bits; and
encoding the first coded bits based on a second nominal code rate to obtain the first codewords.

7. The apparatus of claim 3, wherein generating the first codewords comprises:
forming systematic bits by appending padding bits to the data bits, encoding the systematic bits to generate parity bits, and appending the parity bits to the data bits to generate the first code words.

8. The apparatus of claim 1, wherein the encoding comprises:
generating first codewords;
repeating coded bits associated with the first codewords to generate second codewords; and
applying a mask sequence to the repeated coded bits within each of the second codewords to generate the one or more codewords.

9. The apparatus of claim 8, wherein the mask sequence is based on a scrambling sequence.

10. The apparatus of claim 9, wherein an initial value of the scrambling sequence is a fixed value or a different value.

11. The apparatus of claim 1, wherein:
the encoding comprises:
generating first codewords comprising coded bits; and
repeating the coded bits of the first codewords to generate second codewords; and
the method further comprises:
performing constellation mapping of the repeated coded bits to generate orthogonal frequency division multiplexing (OFDM) symbols; and
applying a mask sequence to data tones of the OFDM symbols when outputting the one or more codewords.

12. The apparatus of claim 11, wherein the mask sequence is based on a sequence of values that comprise +1 and −1 values.

13. The apparatus of claim 12, wherein the mask sequence is based on a known sequence of +1 and −1 values.

14. The apparatus of claim 13, wherein the mask sequence is based on a known sequence used in a long training field (LTF).

15. The apparatus of claim 1, wherein the encoding comprises:
encoding the set of data bits based on the first nominal code rate to generate first codewords; and
further encoding the first codewords based on at least a second nominal code rate to generate second codewords that have the reduced nominal code rate that is a function of at least the first code rate and the second code rate, wherein the one or more codewords comprise the second codewords.

16. The apparatus of claim 15, wherein the one or more processors are further configured to cause the apparatus to:
form a set of systematic bits by appending a set of padding bits to the set of data bits prior to the encoding, encoding the systematic bits based on the first nominal code rate to generate the first codewords and further encoding the first codewords based on the second nominal code rate to generate the second codewords.

17. The apparatus of claim 15, wherein the further encoding comprises performing at least one of a fixed quantity of puncturing of parity bits or a fixed quantity of repetition of data bits.

18. The apparatus of claim 1, wherein the one or more processors are further configured to cause the apparatus to:
form systematic bits by appending padding bits to the data bits, wherein the encoding comprises encoding the systematic bits to generate first codewords of a first size with parity bits, and generating second codewords of a second size with the data bits and the parity bits, wherein the one or more codewords comprise the second codewords.

19. The apparatus of claim 18, wherein a length of the data bits in one of the second codewords is a function of the reduced nominal code rate and a nominal codeword size of the first codewords.

20. The apparatus of claim 19, wherein a length of the padding bits is a function of the length of the data bits in one of the second codewords and the nominal codeword size of the first codewords.

21. The apparatus of claim 19, wherein a size of the one or more second codewords is a function of the length of the data bits in each of the second codewords and the nominal codeword size of the first codewords.

22. The apparatus of claim 1, wherein the one or more processors are further configured to cause the apparatus to at least one of:
adjust a nominal codeword size based on a nominal codeword size of the second codewords; or
adjust at least one of a quantity of coded bits, a quantity of shortening bits, or a quantity of data bits based on the reduced nominal code rate.

23. The apparatus of claim 1, further comprising at least one transceiver configured to transmit the one or more codewords, wherein the apparatus is configured as a wireless station.

24. An apparatus for wireless communication, comprising:
at least one memory comprising computer-executable instructions; and
one or more processors configured to execute the computer-executable instructions and cause the apparatus to:
obtain one or more codewords associated with a reduced nominal code rate; and
decode the one or more codewords, based on at least a first nominal code rate, to recover a set of data bits, wherein the first nominal code rate is higher than the reduced nominal code rate.

25. The apparatus of claim 24, wherein the decoding involves at least one of:
low density parity check (LDPC) decoding; or
binary convolutional code (BCC) decoding.

26. The apparatus of claim 24, wherein the decoding comprises:
decoding the one or more codewords; and
combining decoded bits after the decoding.

27. The apparatus of claim 26, wherein the decoding comprises:
decoding the one or more codewords based on the first nominal code rate to obtain first codewords; and
decoding the first codewords based on a second nominal code rate.

28. The apparatus of claim 26, wherein the decoding comprises:
decoding the one or more codewords to obtain a set of systematic bits that includes a set of padding bits appended to the set of data bits.

29. The apparatus of claim 24, further comprising at least one transceiver configured to receive the one or more codewords, wherein the apparatus is configured as a wireless station.

30. A method for wireless communication at a wireless node, comprising:
obtaining a set of data bits;
encoding the data bits, based on at least a first nominal code rate, to generate one or more codewords associated with a reduced nominal code rate that is lower than the first nominal code rate; and
outputting the one or more codewords.
